(19) United States
(12) Patent Application Publication
(10) Pub. No.: US 2025/0366315 A1
(43) Pub. Date: Nov. 27, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventor: Chun Gi YOU, Yongin-si (KR)

(21) Appl. No.: 19/053,337

(22) Filed: Feb. 13, 2025

(30) Foreign Application Priority Data
May 22, 2024 (KR) 10-2024-0066381

(51) Int. Cl. H10K 59/122; H10K 59/12; H10K 59/124

(52) U.S. Cl. CPC H10K 59/122; H10K 59/1201; H10K 59/124

(57) ABSTRACT

A display device includes: a pixel circuit layer including a pixel circuit on a substrate; an interlayer insulating layer on the pixel circuit layer; and a light emitting element layer on the interlayer insulating layer and including: a light emitting element including an anode electrode, a cathode electrode, and a emission structure electrically connected between the anode electrode and the cathode electrode; a pixel defining layer on the interlayer insulating layer and adjacent to the anode electrode; a trench passing through at least a portion of the pixel defining layer and formed in a boundary area between the sub-pixels; and an insulating layer, the pixel defining layer forms a first slope line having a first angle with a plane where the substrate is located, the insulating layer forms a second slope line having a second angle with the plane, and the second angle is smaller than the first angle.

### CROSS-REFERENCE TO RELATED APPLICATION

The present application claims priority to and the benefit of Korean Patent Application No. 10-2024-0066381, filed on May 22, 2024, in the Korean Intellectual Property Office, the entire disclosure of which is incorporated herein by reference.

### BACKGROUND

### 1. Field

Aspects of some embodiments of the present disclosure relate to a display device, a method of manufacturing the display device, and an electronic device comprising the display device.

### 2. Description of the Related Art

As interest in an information display is recently increased, research and development on a display device is continuously being conducted.

A display device may include sub-pixels respectively including an organic light emitting diode (OLED). The OLED is an active light emitting display element that has an advantage of not only having a relatively wide viewing angle and relatively excellent contrast, but also being able to be driven at a low voltage, being lightweight and thin, and having a fast response speed.

The OLED may include a cathode electrode configured to provide an electron to emit light. The cathode electrode may be electrically connected to another line to receive a cathode signal. The cathode electrode and the line electrically connected to the cathode electrode may desirably be patterned appropriately for an overall display device.

Electrical signals supplied to each adjacent sub-pixel may desirably be distinguished. For example, a risk that electrical signals are to be confused due to a leakage current (lateral leakage) occurring between sub-pixels may occur. Accordingly, a display device that may relatively reduce a risk of a leakage current or the like may be desirable.

The above information disclosed in this Background section is only for enhancement of understanding of the background and therefore the information discussed in this Background section does not necessarily constitute prior art.

### SUMMARY

Aspects of some embodiments of the present disclosure include a display device, a method of manufacturing the display device, and an electronic device comprising the display device, which may relatively reduce a risk of a leakage current or the like.

Aspects of some embodiments of the present disclosure include a display device, a method of manufacturing the display device, and an electronic device comprising the display device, in which a cathode signal path may be closely formed.

Aspects of some embodiments of the present disclosure include a display device, a method of manufacturing the display device, and an electronic device comprising the display device, in which a process operation may be simplified.

According to some embodiments of the present disclosure, a display device may include a display area where sub-pixels are located, and a non-display area. According to some embodiments, the display device may include a pixel circuit layer including a pixel circuit on a substrate, an interlayer insulating layer on the pixel circuit layer, and a light emitting element layer on the interlayer insulating layer. According to some embodiments, in the display area, the light emitting element layer may include a light emitting element including an anode electrode, a cathode electrode, and a emission structure electrically connected between the anode electrode and the cathode electrode, a pixel defining layer on the interlayer insulating layer and adjacent to the anode electrode, and a trench passing through at least a portion of the pixel defining layer and formed in a boundary area between the sub-pixels. According to some embodiments, the light emitting element layer comprises: an insulating layer disposed on the interlayer insulating layer in the non-display area. According to some embodiments, the pixel defining layer may form a first slope line having a first angle with a plane where the substrate is located, the insulating layer may form a second slope line having a second angle with the plane. According to some embodiments, the second angle may be smaller than the first angle.

According to some embodiments, the pixel defining layer may include a plurality of layers having different widths and form a first step portion. According to some embodiments, the insulating layer may include a plurality of layers having different widths and form a second step portion. According to some embodiments, the first step portion and the second step portion may form different structures.

According to some embodiments, the pixel defining layer and the insulating layer may include one or more of silicon oxide (SiₓO_{y}) and silicon nitride (SiₓN_{y}).

According to some embodiments, the pixel defining layer may include a first pixel defining layer, a second pixel defining layer on the first pixel defining layer, and a third pixel defining layer on the second pixel defining layer. According to some embodiments, the insulating layer may include a first insulating layer, a second insulating layer on the first insulating layer, and a third insulating layer on the second insulating layer. According to some embodiments, the first pixel defining layer and the first insulating layer may be located in the same layer. According to some embodiments, the second pixel defining layer and the second insulating layer may be located in the same layer. According to some embodiments, the third pixel defining layer and the third insulating layer may be located in the same layer.

According to some embodiments, the first slope line may be a virtual line connecting ends of each of the first pixel defining layer and the third pixel defining layer. According to some embodiments, the second slope line may be a virtual line connecting ends of each of the first insulating layer and the third insulating layer.

According to some embodiments, the second pixel defining layer may include a material different from that of the first pixel defining layer and the third pixel defining layer. According to some embodiments, the second insulating layer may include a material different from that of the first insulating layer and the third insulating layer.

According to some embodiments, the second pixel defining layer may have a width larger than that of the third pixel defining layer. According to some embodiments, the first pixel defining layer may have a width larger than that of the second pixel defining layer. According to some embodiments, the second insulating layer may have a width larger than that of the third insulating layer. According to some embodiments, the first insulating layer may have a width larger than that of the second insulating layer.

According to some embodiments, the second pixel defining layer may have a width smaller than that of the third pixel defining layer. According to some embodiments, the first pixel defining layer may have a width larger than that of the second pixel defining layer. According to some embodiments, the second insulating layer may have a width larger than that of the third insulating layer. According to some embodiments, the first insulating layer may have a width larger than that of the second insulating layer.

According to some embodiments, the pixel defining layer may include an under-cut portion at least partially recessed.

According to some embodiments, in the non-display area, the light emitting element layer may include a first connection line in the same layer as the anode electrode, an insulating layer covering a portion of the first connection line, and a second connection line in the same layer as the cathode electrode and electrically connected to the first connection line.

According to some embodiments, the display device may further include a reflective layer on the pixel circuit layer in the display area, covered by the interlayer insulating layer, and electrically connecting the anode electrode and the pixel circuit, and a cathode power line on the pixel circuit layer in the non-display area, covered by the interlayer insulating layer, electrically connected to the first connection line, and in the same layer as the reflective layer. According to some embodiments, the trench may partially pass through at least a portion of the interlayer insulating layer. According to some embodiments, the substrate may be a silicon substrate. According to some embodiments, the emission structure may be arranged across the sub-pixels, and at least a portion of the emission structure may be disconnected by the trench.

According to some embodiments of the disclosure, a display device may include a display area including sub-pixel areas. According to some embodiments, the display device may include a pixel circuit layer including a pixel circuit on a substrate, an interlayer insulating layer on the pixel circuit layer, and a light emitting element layer on the interlayer insulating layer. According to some embodiments, in the display area, the light emitting element layer may include an anode electrode, a cathode electrode, and a light emitting element electrically connected between the anode electrode and the cathode electrode, a pixel defining layer on the interlayer insulating layer and covering a portion of the anode electrode, and a trench passing through the pixel defining layer and formed in a boundary area between the sub-pixel areas. According to some embodiments, the pixel defining layer may include a first pixel defining layer, a second pixel defining layer on the first pixel defining layer, and a third pixel defining layer on the second pixel defining layer. According to some embodiments, the second pixel defining layer may have a width smaller than that of the first pixel defining layer and the third pixel defining layer.

According to some embodiments of the present disclosure, a method of manufacturing a display device may include patterning a first connection line on a substrate, forming a base insulating layer covering the first connection line, and including a first base insulating layer, a second base insulating layer on the first base insulating layer, and a third base insulating layer on the second base insulating layer, exposing the second base insulating layer by etching a portion of the third base insulating layer, exposing the first base insulating layer by etching another portion of the third base insulating layer and a portion of the second base insulating layer, exposing the first connection line by etching still another portion of the third base insulating layer, another portion of the second base insulating layer, and a portion of the first base insulating layer, and patterning a second connection line electrically connected to the first connection line.

According to some embodiments, exposing the second base insulating layer may include patterning a first outer photoresist layer including a first photoresist opening, and etching the third base insulating layer using the first outer photoresist layer as an etch mask. According to some embodiments, exposing the first base insulating layer may include patterning a second outer photoresist layer including a second photoresist opening, and etching the second base insulating layer using the second outer photoresist layer as an etch mask. According to some embodiments, exposing the first connection line may include patterning a third outer photoresist layer including a third photoresist opening, and etching the first base insulating layer using the third outer photoresist layer as an etch mask. According to some embodiments, the second photoresist opening may be larger than the first photoresist opening, and the third photoresist opening may be larger than the second photoresist opening.

According to some embodiments, the method may further include patterning an anode electrode on the substrate, and forming a base pixel defining layer covering the anode electrode. According to some embodiments, the base pixel defining layer may include a first base pixel defining layer, a second base pixel defining layer, and a third base pixel defining layer. According to some embodiments, the anode electrode and the first connection line may be formed in the same process. According to some embodiments, the first base pixel defining layer and the first base insulating layer may be formed in the same process. According to some embodiments, the second base pixel defining layer and the second base insulating layer may be formed in the same process. According to some embodiments, the third base pixel defining layer and the third base insulating layer may be formed in the same process.

According to some embodiments, the method may further include providing a third pixel defining layer by patterning a first pixel defining photoresist layer and etching a portion of the third base insulating layer using the first pixel defining photoresist layer as an etch mask, providing a second pixel defining layer by patterning a second pixel defining photoresist layer and etching a portion of the second base insulating layer using the second pixel defining photoresist layer as an etch mask, and providing a first pixel defining layer by patterning a third pixel defining photoresist layer and etching a portion of the first base insulating layer using the third pixel defining photoresist layer as an etch mask. According to some embodiments, the first pixel defining photoresist layer and the first outer photoresist layer may be formed in the same process. According to some embodiments, the second pixel defining photoresist layer and the second outer photoresist layer may be formed in the same process. According to some embodiments, the third pixel defining photoresist layer and the third outer photoresist layer may be formed in the same process. According to some embodiments, exposing the first connection line may include providing a third insulating layer by etching the third base insulating layer, providing a second insulating layer by etching the second base insulating layer, and providing a first insulating layer by etching the first base insulating layer.

According to some embodiments, the second pixel defining photoresist layer may have a width larger than that of the first pixel defining photoresist layer. According to some embodiments, the third pixel defining photoresist layer may have a width larger than that of the second pixel defining photoresist layer.

According to some embodiments, the method may further include forming a trench passing through the first pixel defining layer, the second pixel defining layer, and the third pixel defining layer, and forming a emission structure electrically connected to the anode electrode and covering the first pixel defining layer, the second pixel defining layer, and the third pixel defining layer. According to some embodiments, the insulating layer may form a slope gentler or less than that of the pixel defining layer.

According to some embodiments, the second pixel defining layer may have a width larger than that of the third pixel defining layer. According to some embodiments, the first pixel defining layer may have a width larger than that of the second pixel defining layer. According to some embodiments, the second insulating layer may have a width larger than that of the third insulating layer. According to some embodiments, the first insulating layer may have a width larger than that of the second insulating layer.

According to some embodiments, the second pixel defining layer may have a width smaller than that of the third pixel defining layer. According to some embodiments, the first pixel defining layer may have a width larger than that of the second pixel defining layer. According to some embodiments, the second insulating layer may have a width larger than that of the third insulating layer. According to some embodiments, the first insulating layer may have a width larger than that of the second insulating layer.

According to some embodiments of the present disclosure, an electronic device, may comprise: a processor configured to provide input image data; a display device configured to display an image based on the input image data, the display device including sub-pixel areas; and a power supply configured to supply power to the display device. The display device may comprise: a display area where sub-pixels are located and a non-display area; a pixel circuit layer including a pixel circuit on a substrate; an interlayer insulating layer on the pixel circuit layer; and a light emitting element layer on the interlayer insulating layer. The light emitting element layer may comprise: a light emitting element including an anode electrode, a cathode electrode, and a emission structure electrically connected between the anode electrode and the cathode electrode in the display area; and an insulating layer disposed on the interlayer insulating layer in the non-display area, a pixel defining layer on the interlayer insulating layer and adjacent to the anode electrode; and a trench passing through at least a portion of the pixel defining layer and formed in a boundary area between the sub-pixels. The pixel defining layer may form a first slope line having a first angle with a plane where the substrate is located, the insulating layer forms a second slope line having a second angle with the plane. The second angle may be smaller than the first angle.

According to some embodiments of the present disclosure, a display device, a method of manufacturing the display device, and an electronic device comprising the display device, which may relatively reduce a risk of a leakage current or the like, may be provided.

According to some embodiments of the present disclosure, a display device, a method of manufacturing the display device, and an electronic device comprising the display device, in which a cathode signal path may be closely formed, may be provided.

According to some embodiments of the present disclosure, a display device, a method of manufacturing the display device, and an electronic device comprising the display device, in which a process operation may be simplified, may be provided.

### BRIEF DESCRIPTION OF THE DRAWINGS

The above and other characteristics of some embodiments of the present disclosure will become more apparent by describing in further detail aspects of some embodiments thereof with reference to the accompanying drawings, in which:

FIG. 1 is a schematic plan view illustrating a display device according to some embodiments;

FIG. 2 is a schematic exploded perspective view illustrating a display device according to some embodiments;

FIG. 3 is a schematic plan view illustrating a pixel according to some embodiments;

FIG. 4 is a schematic plan view illustrating a pixel according to some embodiments;

FIG. 5 is a schematic plan view illustrating a pixel according to some embodiments;

FIG. 6 is a schematic cross-sectional view illustrating a display device according to some embodiments;

FIG. 7 is a schematic cross-sectional view illustrating an insulating layer and a pixel defining layer according to some embodiments;

FIG. 8 is a schematic cross-sectional view illustrating a emission structure according to some embodiments;

FIG. 9 is a schematic cross-sectional view illustrating a emission structure according to some embodiments;

FIG. 10 is a schematic cross-sectional view illustrating a display device according to some embodiments;

FIG. 11 is a schematic cross-sectional view illustrating an insulating layer and a pixel defining layer according to some embodiments;

FIGS. 12 to 19 are schematic cross-sectional views for each process operation illustrating a method of manufacturing a display device according to some embodiments;

FIGS. 20 to 23 are schematic cross-sectional views for each process operation illustrating a method of manufacturing a display device according to some embodiments;

FIG. 24 is a block diagram illustrating aspects of a electronic device according to some embodiments of the present disclosure;

FIG. 25 is a perspective view illustrating an application example of the electronic device of FIG. 24; and

FIG. 26 is a diagram illustrating a head mounted display device of FIG. 25 worn by a user.

### DETAILED DESCRIPTION

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

The disclosure relates to a display device, a method of manufacturing the display device, and an electronic device comprising the display device. Hereinafter, a display device, a method of manufacturing the display device, and an electronic device comprising the display device according to some embodiments of the present disclosure are described in more detail with reference to the accompanying drawings.

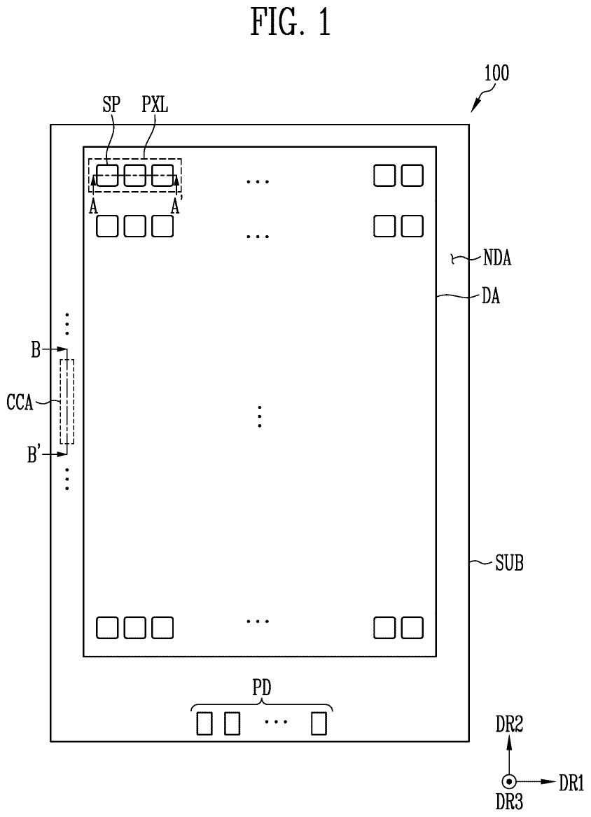

FIG. 1 is a schematic plan view illustrating a display device according to some embodiments.

Referring to FIG. 1, the display device 100 according to some embodiments is configured to emit light.

The display device 100 may include a display area DA and a non-display area NDA. The display device 100 displays images at the display area DA. The non-display area NDA is arranged around (e.g., in a periphery or outside a footprint of) the display area DA.

The display device 100 may include a substrate SUB, the sub-pixels SP, and pads PD.

When the display device 100 is used as a display screen of a head mounted display (HMD) device, a virtual reality (VR) device, a mixed reality (MR) device, an augmented reality (AR) device, or the like, the display device 100 may be positioned very close to user's eyes. In this case, sub-pixels SP of a relatively high integration degree are required. In order to increase an integration degree of the sub-pixels SP, the substrate SUB may be provided as a silicon substrate. The sub-pixels SP may be formed on the substrate SUB, which is the silicon substrate. The display device 100 including a plurality of layers formed on the substrate SUB, which is the silicon substrate, may be referred to as an OLED on silicon (OLEDoS) display device.

The sub-pixels SP are located in the display area DA on the substrate SUB. The sub-pixels SP may be arranged in a matrix shape or configuration along a first direction DR1 and a second direction DR2 crossing the first direction DR1. However, embodiments according to the present disclosure are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

A plane defined in this specification may be a direction extending in the first direction DR1 and the second direction DR2 and may be defined based on a plane where the substrate SUB is located. According to some embodiments, a third direction DR3 may be a thickness direction of the substrate SUB, and the third direction DR3 may be a light emission direction of the display device 100.

The sub-pixels SP may have various shapes in the plan view, and a shape of the sub-pixels SP is not limited to a specific example.

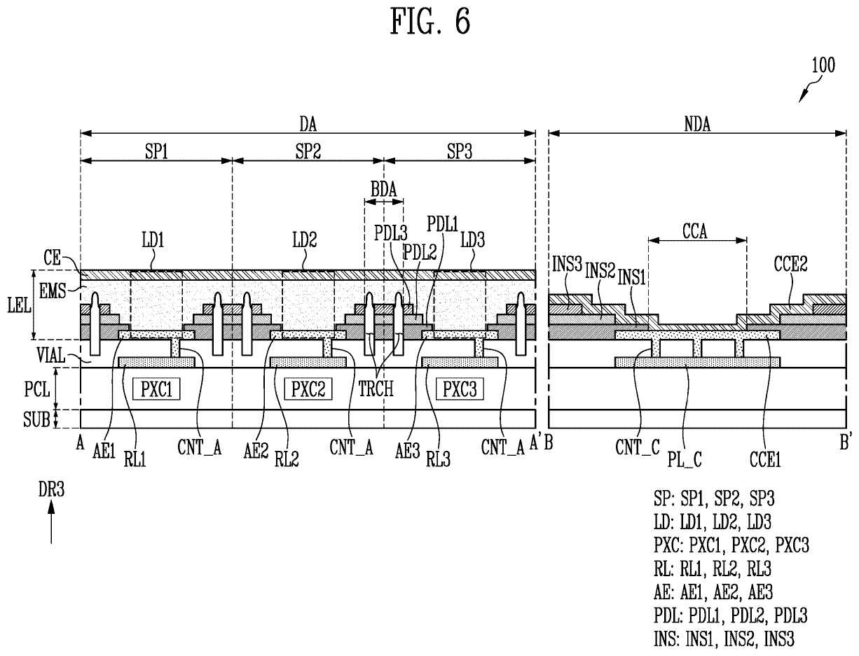

Each of the sub-pixels SP may include at least one light emitting element LD (refer to FIG. 6) configured to generate light. Accordingly, each of the sub-pixels SP may generate light of a specific color, such as red, green, blue, cyan, magenta, or yellow. Two or more sub-pixels SP among the sub-pixels SP may configure a pixel PXL. For example, as shown in FIG. 1, three sub-pixels SP may configure a pixel PXL.

Hereinafter, the disclosure is described based on embodiments in which the sub-pixels SP include a first sub-pixel SP1 providing light of a first color (for example, red), a second sub-pixel SP2 providing light of a second color (for example, green), and a third sub-pixel SP3 providing light of a third color (for example, blue).

According to some embodiments, the first sub-pixel SP1 may be a red pixel and may provide light of a wavelength band of 600 nm to 750 nm. The second sub-pixel SP2 may be a green pixel and may provide light of a wavelength band of 480 nm to 560 nm. The third sub-pixel SP3 may be a blue pixel and may provide light of a wavelength band of 370 nm to 460 nm.

A component for controlling the sub-pixels SP may be located in the non-display area NDA on the substrate SUB. For example, lines connected to the sub-pixels SP (for example, gate lines, data lines, and the like for driving the sub-pixels SP) may be located in the non-display area NDA. In addition, a gate driver, a data driver, a voltage generator, a controller, a temperature sensor, and the like for obtaining driving signals supplied to the sub-pixels SP may be integrated into the non-display area NDA of the display device 100. However, embodiments according to the present disclosure are not limited thereto.

Pads PD are located in the non-display area NDA on the substrate SUB. The pads PD may be electrically connected to the sub-pixels SP through lines. For example, the pads PD may be connected to the sub-pixels SP through data lines.

The pads PD may interface components in the display area DA and the non-display area NDA with other components of the display device 100. According to some embodiments, voltages and signals necessary for an operation of the components included in the display device 100 may be provided from a driver integrated circuit through the pads PD. For example, the data lines may be electrically connected to the driver integrated circuit through the pads PD. For example, power voltages for driving the sub-pixels SP may be received from the driver integrated circuit through the pads PD. For example, a gate control signal for controlling the gate driver may be transmitted from the driver integrated circuit to the gate driver through the pads PD.

According to some embodiments, a circuit board may be electrically connected to the pads PD using a conductive adhesive member such as an anisotropic conductive film. At this time, the circuit board may be a flexible circuit board (FPCB) or a flexible film having a flexible material. The driver integrated circuit may be mounted on the circuit board to be electrically connected to the pads PD.

According to some embodiments, the display area DA may have various shapes. The display area DA may have a closed loop shape including straight and/or curved sides. For example, the display area DA may have shapes such as a polygon, a circle, a semicircle, and an ellipse.

According to some embodiments, the display device 100 may have a flat display surface. According to some embodiments, the display device 100 may have a display surface that is at least partially round. According to some embodiments, the display device 100 may be bendable, foldable, or rollable. In these cases, the display device 100 and/or the substrate SUB may include materials having a flexible property.

The display device 100 may further include a cathode connection area CCA.

The cathode connection area CCA may be located in the non-display area NDA. The cathode connection area CCA may be located at a periphery of the display area DA. According to some embodiments, the cathode connection area CCA may partially surround an edge of the display area DA. An area where the cathode connection area CCA is formed is not necessarily limited to the example described above.

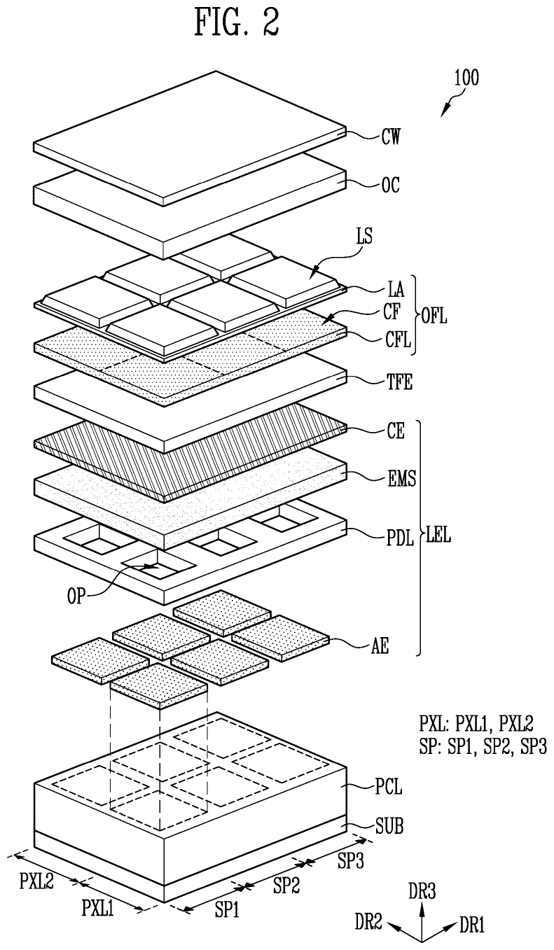

The cathode connection area CCA may be a portion of a path through which a cathode voltage for operating the pixel PXL is supplied. For example, the cathode voltage may be provided adjacent to the cathode connection area CCA through a cathode power line PL_C (refer to FIG. 6) formed generally at a lower portion, may be provided to first and second connection lines CCE1 and CCE2 (refer to FIG. 6) electrically connected to each other in the cathode connection area CCA, and may be supplied throughout the pixels PXL through a cathode electrode CE (refer to FIG. 2) electrically connected to the second connection line CCE2.

FIG. 2 is a schematic exploded perspective view illustrating a display device according to some embodiments. In FIG. 2, for clear and concise description, a portion of the display device 100 corresponding to two pixels PXL1 and PXL2 among the pixels PXL is schematically shown. A portion of the display device 100 corresponding to remaining pixels may be similarly configured.

Referring to FIG. 2, each of the first and second pixels PXL1 and PXL2 may include first to third sub-pixels SP1 to SP3. However, embodiments according to the present disclosure are not limited thereto. For example, each of the first and second pixels PXL1 and PXL2 may include four sub-pixels or two sub-pixels.

In FIG. 2, the first to third sub-pixels SP1 to SP3 have quadrangle shapes when viewed from a third direction DR3 crossing the first and second directions DR1 and DR2 (e.g., in a plan view), and have sizes equal to each other. However, embodiments according to the present disclosure are not limited thereto. The first to third sub-pixels SP1 to SP3 may be modified to have various shapes.

The display device 100 may include the substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. According to some embodiments, the substrate SUB may include a glass substrate. According to some embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include various conductive materials, and embodiments are not limited to a specific example. The circuit elements may include a pixel circuit PXC (refer to FIG. 6) for each of the first to third sub-pixels SP1 to SP3. The pixel circuit PXC may include transistors and one or more capacitors.

The light emitting element layer LEL may include anode electrodes AE, a pixel defining layer PDL, a emission structure EMS, and a cathode electrode CE.

The anode electrodes AE may be located on the pixel circuit layer PCL. The anode electrodes AE may be electrically connected to the circuit elements of the pixel circuit layer PCL.

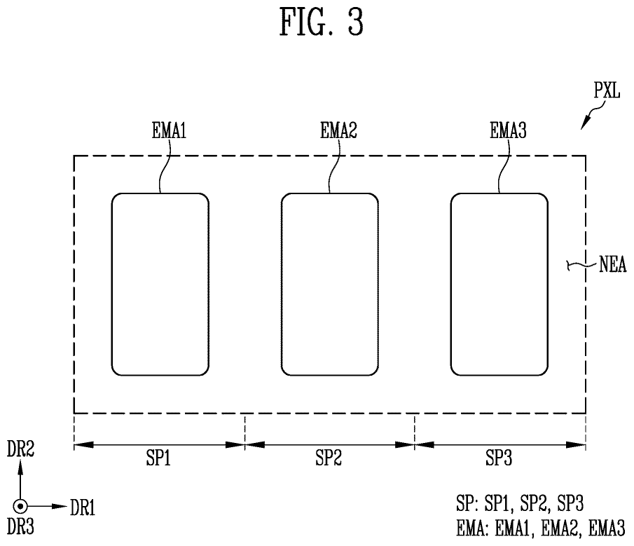

The pixel defining layer PDL is located on the anode electrodes AE. The pixel defining layer PDL may include an opening OP exposing a portion of each of the anode electrodes AE. The opening OP of the pixel defining layer PDL may be understood as emission areas EMA (refer to FIG. 3) corresponding to the first to third sub-pixels SP1 to SP3, respectively.

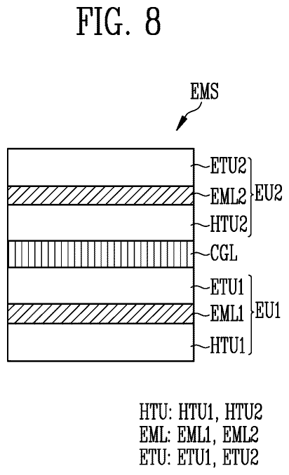

The emission structure EMS may be located on the anode electrodes AE exposed by the opening OP of the pixel defining layer PDL. The emission structure EMS may include a light emitting layer EML (refer to FIG. 8) configured to generate light, an electron transport unit ETU (refer to FIG. 8) configured to transport an electron, a hole transport unit HTU (refer to FIG. 8) configured to transport a hole, and the like.

According to some embodiments, the emission structure EMS may fill the opening OP of the pixel defining layer PDL, and may be entirely arranged on the pixel defining layer PDL. In other words, the emission structure EMS may extend across the first to third sub-pixels SP1 to SP3. In this case, at least a portion of layers in the emission structure EMS may be disconnected or bent at boundaries between the first to third sub-pixels SP1 to SP3.

The cathode electrode CE may be located on the emission structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the emission structure EMS. The cathode electrode CE may be configured to supply a cathode voltage to the emission structure EMS.

According to some embodiments, the cathode electrode CE may be a thin metal layer having a thickness sufficient to transmit the light emitted from the emission structure EMS. The cathode electrode CE may be formed of a metal material or a transparent conductive material to have a relatively thin thickness. According to some embodiments, the cathode electrode CE may include at least one of various transparent conductive materials including indium tin oxide (ITO), indium zinc oxide (IZO), indium gallium zinc oxide (IGZO), aluminum zinc oxide (AZO), indium tin zinc oxide (ITZO), zinc oxide (ZnO), or tin oxide (SnO₂). According to some embodiments, the cathode electrode CE may include at least one of silver (Ag), magnesium (Mg), and/or a mixtures thereof. However, a material of the cathode electrode CE is not limited thereto.

It may be understood that the anode electrodes AE, a portion of the emission structure EMS overlapping it, and a portion of the cathode electrode CE overlapping it configure a light emitting element LD. In other words, each of the light emitting elements LD of the first to third sub-pixels SP1 to SP3 may include an anode electrode AE, a portion of the emission structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer EML of the emission structure EMS to form excitons, and when the excitons transits from an excited state to a ground state, light may be generated. A luminance of light may be determined according to an amount of a current flowing through the light emitting layer EML. According to a configuration of the light emitting layer EML, a wavelength range of the generated light may be determined.

The encapsulation layer TFE is located on the cathode electrode CE. The encapsulation layer TFE may cover the light emitting element layer LEL and the pixel circuit layer PCL. The encapsulation layer TFE may be configured to prevent or reduce instances of contaminants such as oxygen, moisture, and/or the like permeating to the light emitting element layer LDL. According to some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB) resin. However, materials of the organic and the inorganic layers of the encapsulation layer TFE are not limited thereto.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL is configured to filter the light emitted from the emission structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the emission structure EMS of each sub-pixel, at least a portion of the color filters CF may be omitted.

The lens array LA is located on the color filter layer CFL. The lens array LA may include lenses LS respectively corresponding to the first to third sub-pixels SP1 to SP3. Each of the lenses LS may improve light output efficiency by outputting the light emitted from the emission structure EMS to an intended path. The lens array LA may have a relatively high refractive index. For example, the lens array LA may have a refractive index higher than that of the overcoat layer OC. According to some embodiments, the lenses LS may include an organic material. According to some embodiments, the lenses LS may include an acrylic material. However, a material of the lenses LS is not limited thereto.

The overcoat layer OC may be located on the lens array LA. The overcoat layer OC may cover the optical functional layer OFL, the encapsulation layer TFE, the emission structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than that of the lens array LA.

The cover window CW may be located on the overcoat layer OC. The cover window CW is configured to protect layers thereunder. The cover window CW may have a refractive index higher than that of the overcoat layer OC. The cover window CW may include glass, but embodiments are not limited thereto. For example, the cover window CW may be an encapsulation glass configured to protect components located thereunder. According to some embodiments, the cover window CW may be omitted.

FIG. 3 is a schematic plan view illustrating a pixel according to some embodiments.

Referring to FIG. 3, the pixel PXL may include sub-pixels SP arranged in the first direction DR1. For example, the sub-pixels SP may include a first sub-pixel SP1, a second sub-pixel SP2, and a third sub-pixel SP3 arranged in the first direction DR1. The emission areas EMA may include first to third emission areas EMA1 to EMA3.

The first sub-pixel SP1 may include the first emission area EMA1 and a non-emission area NEA around the first emission area EMA1. The second sub-pixel SP2 may include the second emission area EMA2 and a non-emission area NEA around the second emission area EMA2. The third sub-pixel SP3 may include the third emission area EMA3 and a non-emission area NEA around the third emission area EMA3.

The first emission area EMA1 may be an area where light is emitted from a portion of the emission structure EMS corresponding to the first sub-pixel SP1 (for example, a first emission structure). The second emission area EMA2 may be an area where light is emitted from a portion of the emission structure EMS corresponding to the second sub-pixel SP2 (for example, a second emission structure). The third emission area EMA3 may be an area where light is emitted from a portion of the emission structure EMS corresponding to the third sub-pixel SP3 (for example, a third emission structure). As described with reference to FIG. 2, each emission area may be understood as the opening OP of the pixel defining layer PDL corresponding to each of the first sub-pixel SP1, the second sub-pixel SP2, and the third sub-pixel SP3.

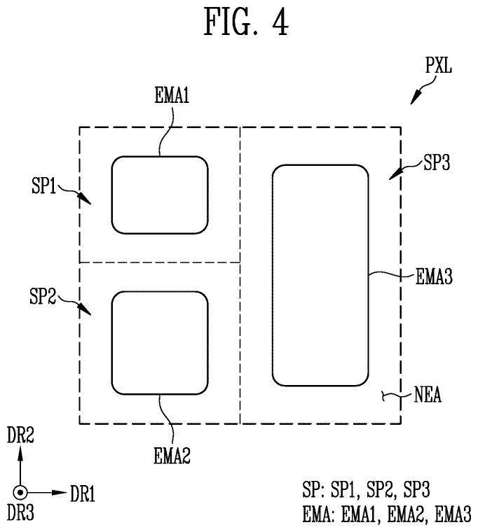

FIG. 4 is a schematic plan view illustrating a pixel according to some embodiments.

Referring to FIG. 4, the first sub-pixel SP1 and the second sub-pixel SP2 may be arranged in the second direction DR2. The third sub-pixel SP3 may be arranged in the first direction DR1 with respect to each of the first and second sub-pixels SP1 and SP2.

The second sub-pixel SP2 may have the area larger than that of the first sub-pixel SP1, and the third sub-pixel SP3 may have the area larger than that of the second sub-pixel SP2. Accordingly, the second emission area EMA2 may have the area larger than the first emission area EMA1, and the third emission area EMA3 may have the area larger than that of the second emission area EMA2. However, embodiments according to the present disclosure are not limited thereto. For example, the first and second sub-pixels SP1 and SP2 may have the same (or substantially the same) area, and the third sub-pixel SP3 may have the area larger than that of each of the first and second sub-pixels SP1 and SP2. As described above, the areas of the first to third sub-pixels SP1 to SP3 may be variously modified according to embodiments.

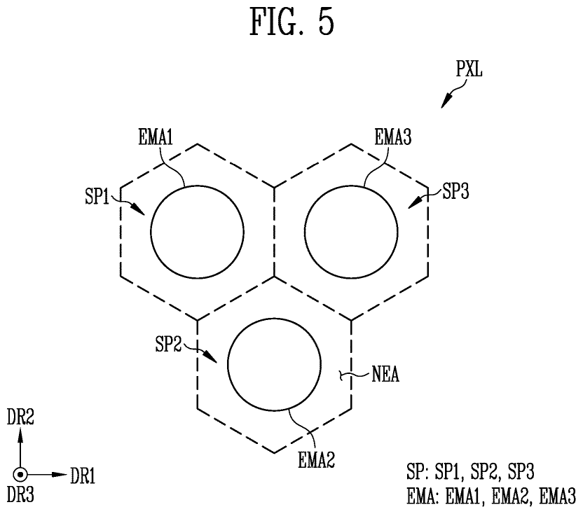

FIG. 5 is a schematic plan view illustrating a pixel according to some embodiments.

Referring to FIG. 5, the first to third sub-pixels SP1 to SP3 may have polygonal shapes when viewed in the third direction DR3 (e.g., in a plan view). For example, shapes of the first to third sub-pixels SP1 to SP3 may be hexagonal shapes as shown in FIG. 5. However, embodiments according to the present disclosure are not limited thereto.

The first to third emission areas EMA1 to EMA3 may have circular shapes when viewed in the third direction DR3 (e.g., in a plan view). However, embodiments according to the present disclosure are not limited thereto. For example, each of the first to third emission areas EMA1 to EMA3 may have a polygonal shape.

The first and third sub-pixels SP1 and SP3 may be arranged in the first direction DR1. The second sub-pixel SP2 may be arranged in a direction inclined by an acute angle based on the second direction DR2 (or a diagonal direction) with respect to the first sub-pixel SP1.

An arrangement of the sub-pixels shown in FIGS. 3 to 5 is examples, and embodiments are not limited thereto. Each pixel PXL may include two or more sub-pixels SP, the sub-pixels SP may be arranged in various methods, the respective sub-pixels SP may have various shapes, and respective emission areas EMA thereof may also have various shapes.

With reference to FIGS. 6 to 9, a cross-sectional structure of the display device 100 according to some embodiments of the present disclosure is described.

First, referring to FIGS. 6 to 9, a display device 100 according to some embodiments of the present disclosure is described.

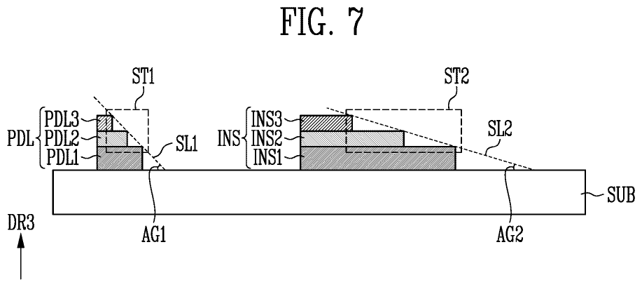

FIG. 6 is a schematic cross-sectional view illustrating the display device according to some embodiments. FIG. 7 is a schematic cross-sectional view illustrating an insulating layer and a pixel defining layer according to some embodiments.

FIG. 6 shows the first to third sub-pixels SP1 to SP3 in the display area DA as a schematic cross-sectional structure taken along line A-A′ of FIG. 1, and the cathode connection area CCA in the non-display area NDA as a schematic cross-sectional structure taken along the line B-B′ of FIG. 1.

With reference to FIGS. 6 and 7, a disposition relationship between layers in the display area DA and layers in the cathode connection area CCA may be clearly understood. For convenience of description, other layers on a light emitting element layer LEL are omitted in FIG. 6, and other layers except for the substrate SUB, an insulating layer INS, and the pixel defining layer PDL are omitted in FIG. 7.

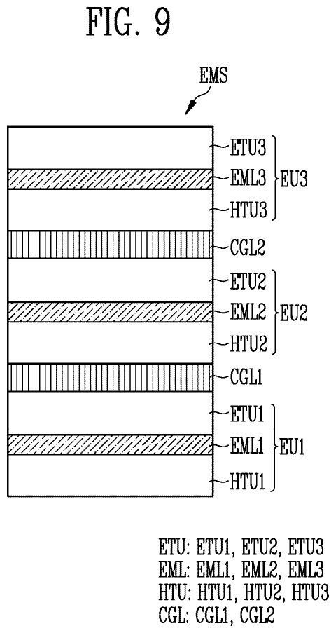

FIG. 8 is a schematic cross-sectional view illustrating a emission structure according to some embodiments. FIG. 9 is a schematic cross-sectional view illustrating a emission structure according to some embodiments.

Referring to FIGS. 6 to 9, the display device 100 may include the substrate SUB, and may include layers on the substrate SUB in the display area DA and layers on the substrate SUB in the non-display area NDA.

The substrate SUB is arranged across the display area DA and the non-display area NDA and may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, or a semiconductor on insulator (SeOI) layer. According to some embodiments, the substrate SUB may include a glass substrate. According to some embodiments, the substrate SUB may include a polyimide (PI) substrate.

The display device 100 may include the pixel circuit layer PCL.

The pixel circuit layer PCL may be located on the substrate SUB. The pixel circuit layer PCL may be configured to drive the light emitting element LD and may include pixel circuits PXC located in the display area DA. The pixel circuit layer PCL may include conductive layers and insulating layers, and the conductive layers may form the pixel circuit PXC. The pixel circuit PXC may include a first pixel circuit PXC1 configured to drive the first sub-pixel SP1 (for example, a first light emitting element LD1), a second pixel circuit PXC2 configured to drive the second sub-pixel SP2 (for example, a second light emitting element LD2), and a third pixel circuit PXC3 configured to drive the third sub-pixel SP3 (for example, a third light emitting element LD3).

The display device 100 may include a reflective layer RL.

The reflective layer RL may be located on the pixel circuit layer PCL in the display area DA, and may overlap the anode electrode AE in the plan view. The reflective layer RL may include a first reflective layer RL1 included in the first sub-pixel SP1 and overlapping the first anode electrode AE1, a second reflective layer RL2 included in the second sub-pixel SP2 and overlapping the second anode electrode AE2, and a third reflective layer RL3 included in the third sub-pixel SP3 and overlapping the third anode electrode AE3.

The reflective layer RL may function as a full mirror that reflects the light emitted from the emission structure EMS toward a display screen (or the cover window CW). At least a portion of the reflective layer RL may include metal materials suitable for reflecting light. For example, the metal materials may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and/or an alloy of two or more materials selected from them.

The reflective layer RL may be electrically connected to the pixel circuit PXC. For example, the respective first to third reflective layers RL1 to RL3 may be electrically connected to the first to third pixel circuits PXC1 to PXC3. According to some embodiments, the reflective layer RL may be a bridge structure to which an anode voltage for the light emitting element LD is supplied.

The display device 100 may include a cathode power line PL_C.

The cathode power line PL_C may be located on the pixel circuit layer PCL in the non-display area NDA. At least a portion of the cathode power line PL_C may be located in the cathode connection area CCA.

The cathode power line PL_C may be patterned in the same process as the reflective layer RL, located in the same layer as the reflective layer RL, and may include the same conductive material as the reflective layer RL.

The cathode power line PL_C may be a path through which a cathode voltage to be supplied to the cathode electrode CE of the light emitting element LD is applied. For example, the cathode voltage supplied by the cathode power line PL_C may be applied to the cathode electrode CE through an electrical path.

The display device 100 may include an interlayer insulating layer VIAL.

The interlayer insulating layer VIAL may be located on the pixel circuit layer PCL. According to some embodiments, the interlayer insulating layer VIAL may be a via layer. For example, an anode contact portion CNT_A may be formed in the interlayer insulating layer VIAL. The interlayer insulating layer VIAL may cover the reflective layers RL and the cathode power line PL_C, and may be a planarization layer. The interlayer insulating layer VIAL may include various organic materials. However, embodiments according to the present disclosure are not limited thereto. For example, the interlayer insulating layer VIAL may include an inorganic material.

The display device 100 may include a light emitting element layer LEL. The display device 100 (or the light emitting element layer LEL) may include the anode electrode AE, a first connection line CCE1, the pixel defining layer PDL, a trench TRCH, the insulating layer INS, the emission structure EMS, the cathode electrode CE, and a second connection line CCE2.

The anode electrode AE may be located on the interlayer insulating layer VIAL in the display area DA. The anode electrode AE may be electrically connected to the reflective layer RL through the anode contact portion CNT_A passing through the interlayer insulating layer VIAL.

The anode electrode AE may include a first anode electrode AE1 included in the first sub-pixel SP1 and forming the first light emitting element LD1, a second anode electrode AE2 included in the second sub-pixel SP2 and forming the second light emitting element LD2, and a third anode electrode AE3 included in the third sub-pixel SP3 and forming the third light emitting element LD3.

The anode electrode AE may include at least one of transparent conductive materials such as indium tin oxide (ITO), indium zinc oxide (IZO), zinc oxide (ZnOₓ), indium gallium zinc oxide (IGZO), or indium tin zinc oxide (ITZO). However, a material of the anode electrode AE is not limited thereto. For example, the anode electrode AE may include titanium nitride.

The first connection line CCE1 may be located on the interlayer insulating layer VIAL in the non-display area NDA. At least a portion of the first connection line CCE1 may be located in the cathode connection area CCA. The first connection line CCE1 may be electrically connected to the cathode power line PL_C through a cathode contact portion CNT_C passing through the interlayer insulating layer VIAL. According to some embodiments, the cathode contact portion CNT_C may include a plurality of cathode contact portions CNT_C.

The first connection line CCE1 may be patterned in the same process as the anode electrode AE, may be located in the same layer as the anode electrode AE, and may include the same conductive material as the anode electrode AE.

According to some embodiments, the first connection line CCE1 may be a first cathode connection line.

The pixel defining layer PDL may be located on the interlayer insulating layer VIAL in the display area DA. The pixel defining layer PDL may be adjacent to the anode electrode AE. The pixel defining layer PDL may partially cover the anode electrode AE and expose a portion of the anode electrode AE.

The pixel defining layer PDL may include a plurality of layers having different widths, and thus the pixel defining layer PDL may form a first step portion ST1. As the first step portion ST1 is formed, at least a portion of the pixel defining layer PDL may have a step shape of cross-section.

In this specification, a width may be a direction in which the plane where the substrate SUB is located extends, and may be defined based on a direction in which the sub-pixels SP are adjacent to each other.

For example, the pixel defining layer PDL may include a first pixel defining layer PDL1 having different widths, a second pixel defining layer PDL2 on the first pixel defining layer PDL1, and a third pixel defining layer PDL3 on the second pixel defining layer PDL2.

According to some embodiments, the first pixel defining layer PDL1 may have a width larger than that of the second and third pixel defining layers PDL2 and PDL3. The second pixel defining layer PDL2 may have a width larger than that of the third pixel defining layer PDL3. Accordingly, the first step portion ST1 may be formed in an area between the first pixel defining layer PDL1 and the second pixel defining layer PDL2 and an area between the second pixel defining layer PDL2 and the third pixel defining layer PDL3.

According to some embodiments, as layers having different widths are stacked in the pixel defining layer PDL, a first slope line SL1 may be formed. For example, because the first pixel defining layer PDL1 may have the width larger than that of the second and third pixel defining layers PDL2 and PDL3, and the second pixel defining layer PDL2 may have the width larger than that of the third pixel defining layer PDL3, the pixel defining layer PDL may form the first slope line SL1 forming a first angle AG1 with respect to the plane where the substrate SUB is located.

The first slope line SL1 may be a virtual line generally connecting ends of each of the first to third pixel defining layers PDL1 to PDL3. For example, the first slope line SL1 may be a virtual line connecting ends of the lowermost layer of the pixel defining layer PDL (for example, the first pixel defining layer PDL1) and the uppermost layer of the pixel defining layer PDL (for example, the third pixel defining layer PDL3).

The pixel defining layer PDL may include an inorganic material. For example, the pixel defining layer PDL may include one or more of silicon oxide (SiₓO_{y}) and silicon nitride (SiₓN_{y}).

Among a plurality of layers forming the pixel defining layer PDL, adjacent layers may include different materials. For example, the first pixel defining layer PDL1 and the second pixel defining layer PDL2 may include different materials. The second pixel defining layer PDL2 and the third pixel defining layer PDL3 may include different materials.

According to some embodiments, the first pixel defining layer PDL1 may include silicon nitride (SiₓN_{y}), the second pixel defining layer PDL2 may include silicon oxide (SiₓO_{y}), and the third pixel defining layer PDL3 may include silicon nitride (SiₓN_{y}). Alternatively, according to some embodiments, the first pixel defining layer PDL1 may include silicon oxide (SiₓO_{y}), the second pixel defining layer PDL2 may include silicon nitride (SiₓN_{y}), and the third pixel defining layer PDL3 may include silicon oxide (SiₓO_{y}).

The insulating layer INS may be located on the interlayer insulating layer VIAL in the non-display area NDA, may partially cover the first connection line CCE1, and may expose at least a portion of the first connection line CCE1.

The insulating layer INS may include a plurality of layers having different widths, and thus the insulating layer INS may form a second step portion ST2. As the second step portion ST2 is formed, at least a portion of the insulating layer INS may have a step shape of cross-section.

For example, the insulating layer INS may include a first insulating layer INS1 having different widths, a second insulating layer INS2 on the first insulating layer INS1, and a third insulating layer INS3 on the second insulating layer INS2.

According to some embodiments, the first insulating layer INS1 may have a width larger than that of the second and third insulating layers INS2 and INS3. The second insulating layer INS2 may have a width larger than that of the third insulating layer INS3. Accordingly, the second step portion ST2 may be formed in an area between the first insulating layer INS1 and the second insulating layer INS2 and an area between the second insulating layer INS2 and the third insulating layer INS3.

According to some embodiments, as layers having different widths are stacked in the insulating layer INS, a second slope line SL2 may be formed. For example, because the first insulating layer INS1 may have the width larger than that of the second and third insulating layers INS2 and INS3, and the second insulating layer INS2 may have a width larger than that of the third insulating layer INS3, the insulating layer INS may form a second slope line SL2 forming a second angle AG2 with respect to the plane where the substrate SUB is located may be formed.

The second slope line SL2 may be a virtual line generally connecting ends of each of the first to third insulating layers INS1 to INS3. For example, the second slope line SL2 may be a virtual line connecting ends of the lowermost layer of the insulating layer INS (for example, the first insulating layer INS1) and the uppermost layer of the insulating layer INS (for example, the third insulating layer INS3).

The insulating layer INS may include an inorganic material. For example, the insulating layer INS may include one or more of silicon oxide (SiₓO_{y}) and silicon nitride (SiₓN_{y}).

The insulating layer INS may be patterned in the same process as the pixel defining layer PDL, located in the same layer as the pixel defining layer PDL, and may include the same conductive material as the pixel defining layer PDL.

For example, the first insulating layer INS1 may be patterned in the same process as the first pixel defining layer PDL1, located in the same layer as the first pixel defining layer PDL1, and may include the same inorganic material as the first pixel defining layer PDL1. The second insulating layer INS2 may be patterned in the same process as the second pixel defining layer PDL2, located in the same layer as the second pixel defining layer PDL2, and may include the same inorganic material as the second pixel defining layer PDL2. The third insulating layer INS3 may be patterned in the same process as the third pixel defining layer PDL3, located in the same layer as the third pixel defining layer PDL3, and may include the same inorganic material as the third pixel defining layer PDL3.

According to some embodiments, the insulating layer INS may have a relatively gentle slope compared to the pixel defining layer PDL. For example, the second slope line SL2 may have a slope gentler or less than that of the first slope line SL1. The second angle AG2 may be smaller than the first angle AG1. According to some embodiments, the first step portion ST1 and the second step portion ST2 may have different structures.

The first step portion ST1 of the pixel defining layer PDL may be prepared to cut at least a portion of common layers of the emission structure EMS arranged across the sub-pixels SP. The first step portion ST1 may form a structure of which a slope is relatively steep, and the first angle AG1 may be relatively large.

The second step portion ST2 of the insulating layer INS may be patterned in the same process as the pixel defining layer PDL, and may be prepared so that the second connection line CCE2 is not disconnected so that a cathode connection path may be maintained. The second step portion ST2 may form a structure having a relatively gentle slope, and the second angle AG2 may be relatively small.

That is, according to some embodiments, structures patterned in the same process may be prepared to have an appropriate cross-sectional structure according to a performed function.

Accordingly, because a portion of the pixel defining layer PDL may appropriately cut a portion of the common layers of the emission structure EMS, a risk of a leakage current between the sub-pixels SP may be relatively reduced. In addition, because the insulating layer INS may prevent or reduce instances of the second connection line CCE2 forming a cathode connection path being disconnected, the cathode connection path may be thoroughly formed.

In addition, because configurations for preparing the technical effects described above may be patterned in the same process, process operations may be simplified and a process cost may be relatively reduced.

The trench TRCH may be located adjacent to the anode electrode AE in the plane view. The trench TRCH may define a boundary area BDA between the sub-pixels SP and may be located between adjacent anode electrodes AE. The trench TRCH may cause formation of a discontinuous portion (discontinuity) in the emission structure EMS at the boundary area BDA. For example, at least a portion of the emission structure EMS may be disconnected or bent in the boundary area BDA due to the trench TRCH.

The trench TRCH may pass through the pixel defining layer PDL and, according to some embodiments, may partially pass through a portion of the interlayer insulating layer VIAL. For example, the trench TRCH may pass through at least a portion of the pixel defining layer PDL.

The trench TRCH may include a void. As the trench TRCH forms the void, at least a portion of the emission structure EMS formed to cover the trench TRCH may be disconnected or bent. For example, at least a portion of layers commonly formed in the first to third sub-pixels SP1 to SP3 among a plurality of layers included in the emission structure EMS may be disconnected. For example, a portion of a charge generation layer CGL (refer to FIG. 8) or a hole transport unit HTU included in the emission structure EMS may be disconnected by the trench TRCH.

The emission structure EMS may be located on the anode electrode AE exposed by the pixel defining layer PDL in the display area DA, and may be arranged across the first to third sub-pixels SP1 to SP3. As described above, the emission structure EMS may be at least partially disconnected or bent in the boundary area BDA by the trench TRCH. Accordingly, a risk of a leakage current may be relatively reduced, and the sub-pixels SP may have an operation characteristic having improved reliability.

The emission structure EMS may include a multilayer structure electrically connected between the anode electrode AE and the cathode electrode CE.

According to some embodiments (refer to FIG. 8), the emission structure EMS may have a tandem structure in which first and second light emitting units EU1 and EU2 are stacked. The emission structure EMS may be configured identically (or substantially identically) in each of the first to third light emitting elements LD1 to LD3.

Each emission structure EMS may include the hole transport unit HTU, the light emitting layer EML, and the electron transport unit ETU, and may further include the charge generation layer CGL. Each of layers forming the emission structure EMS may include an organic material, and according to some embodiments, may further include a metal-containing compound or an inorganic material such as a quantum dot.

The hole transport unit HTU may include a multilayer structure having a plurality of layers respectively including different materials. As an example, the hole transport unit HTU may include a hole injection layer and a hole transport layer, and according to some embodiments, may further include a light emitting auxiliary layer, an electron blocking layer, and the like.

The light emitting layer EML may include a material that may emit light of a color. The light emitting layer EML may include a host and a dopant. The host of the light emitting layer EML may be a light emitting material that may capture carriers (electrons and holes) for light generation, and may induce an exciton to be efficiently generated. The dopant may include a phosphorescent dopant or a fluorescent dopant. According to some embodiments, an examples of the dopant is not particularly limited. According to some embodiments, the dopant may include an organic material, may include a metal complex or the like.

The electron transport unit ETU may include a multilayer structure having a plurality of layers respectively including different materials. The electron transport unit ETU may include an electron injection layer and an electron transport layer, and according to some embodiments, may further include an electron buffer layer, a hole blocking layer, and the like.

The first light emitting unit EU1 may include a first light emitting layer EML1, a first electron transport unit ETU1, and a first hole transport unit HTU1. The first light emitting layer EML1 may be located between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be located between the second electron transport unit ETU2 and the second hole transport unit HTU2.

A connection layer, which may be provided in a form of a charge generation layer CGL, may be located between the first light emitting unit EU1 and the second light emitting unit EU2 to electrically connect the first light emitting unit EU1 and the second light emitting unit EU2 to each other. According to some embodiments, the charge generation layer CGL may have a stack structure of a p dopant layer and an n dopant layer. For example, the p dopant layer may include a p-type dopant such as HAT-CN, TCNQ, and NDP-9, and the n dopant layer may include an alkali metal, an alkaline earth metal, a lanthanide metal, or a combination thereof. However, embodiments according to the present disclosure are not limited thereto.

According to some embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate light of a blue color, and the second light emitting layer EML2 may generate light of a yellow color. According to some embodiments, the second light emitting layer EML2 may include a structure in which a first sub light emitting layer configured to generate light of a red color and a second sub light emitting layer configured to generate light of a green color are stacked. The light of the red color and the light of the green color may be mixed, and thus the light of the yellow color may be provided. In this case, an intermediate layer configured to perform a function of transporting holes and/or blocking transport of electrons may be further located between the first and second sub light emitting layers.

According to some embodiments (refer to FIG. 9), the emission structure EMS may have a tandem structure in which first to third light emitting units EU1 to EU3 are stacked. The emission structure EMS may be configured identically (or substantially identically) in each of the first to third light emitting elements LD1 to LD3 of FIG. 6.

The first light emitting unit EU1 may include a first light emitting layer EML1, a first electron transport unit ETU1, and a first hole transport unit HTU1. The first light emitting layer EML1 may be located between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be located between the second electron transport unit ETU2 and the second hole transport unit HTU2. The third light emitting unit EU3 may include a third light emitting layer EML3, a third electron transport unit ETU3, and a third hole transport unit HTU3. The third light emitting layer EML3 may be located between the third electron transport unit ETU3 and the third hole transport unit HTU3.

A first charge generation layer CGL1 is located between the first light emitting unit EU1 and the second light emitting unit EU2. A second charge generation layer CGL2 is located between the second light emitting unit EU2 and the third light emitting unit EU3.

According to some embodiments, the first to third light emitting layers EML1 to EML3 may generate light of different colors. Light emitted from each of the first to third light emitting layers EML1 to EML3 may be mixed and may be viewed as white light. For example, the first light emitting layer EML1 may generate light of a blue color, the second light emitting layer EML2 may generate light of a green color, and the third light emitting layer EML3 may generate light of a red color.

The cathode electrode CE may be located on the emission structure EMS. The cathode electrode CE may be commonly provided to the first to third sub-pixels SP1 to SP3. The cathode electrode CE may function as a half mirror that partially transmits and partially reflects the light emitted from the emission structure EMS. However, embodiments according to the present disclosure are not limited thereto.

The second connection line CCE2 may be located in the non-display area NDA and may cover the insulating layer INS and the first connection line CCE1. At least a portion of the second connection line CCE2 may be located in the cathode connection area CCA. According to some embodiments, the second connection line CCE2 may contact a portion of an upper surface of the first connection line CCE1 exposed by the insulating layer INS. The cathode connection area CCA may be an area where the first and second connection lines CCE1 and CCE2 contact each other.

The second connection line CCE2 may be patterned in the same process as the cathode electrode CE and may include the same conductive material as the cathode electrode CE.

According to some embodiments, the second connection line CCE2 may be a second cathode connection line.

According to some embodiments, the second connection line CCE2 may cover the insulating layer INS forming a relatively gentle slope, and a cathode connection path formed by the second connection line CCE2 may be thoroughly maintained. Accordingly, the cathode voltage supplied through the cathode power line PL_C may be appropriately applied to the cathode electrode CE via the first and second connection lines CCE1 and CCE2. According to some embodiments, the second connection line CCE2 may extend to an area directly adjacent to the display area DA and be connected to the cathode electrode CE. According to some embodiments, the second connection line CCE2 and the cathode electrode CE may be integrally formed.

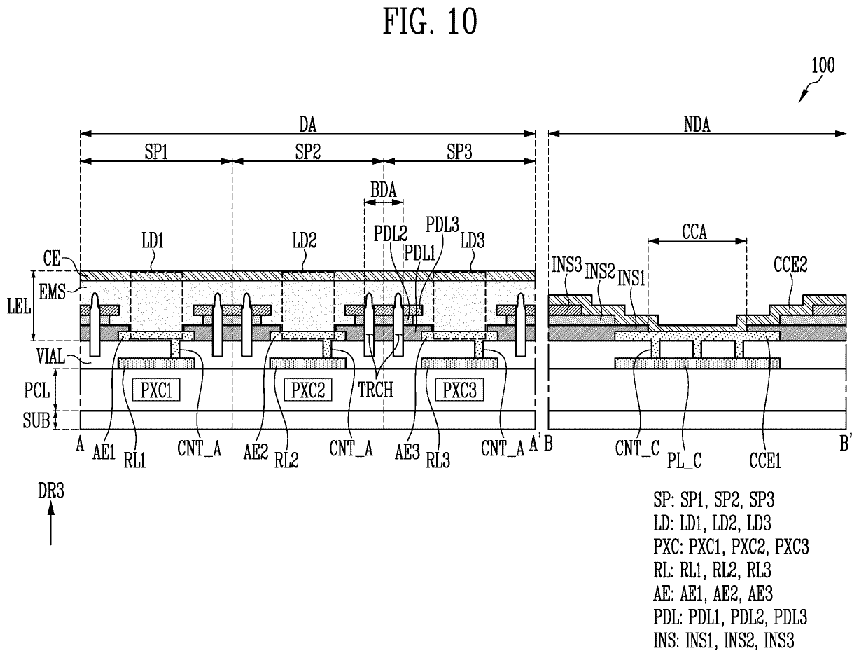

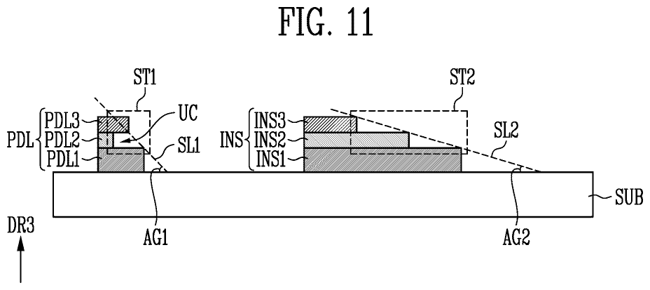

Next, with reference to FIGS. 10 and 11, further details of the display device 100 according to some embodiments is described. Some disclosure that may overlap the content described above may be briefly described or may not be repeated.

FIG. 10 is a schematic cross-sectional view illustrating the display device according to some embodiments. FIG. 11 is a schematic cross-sectional view illustrating an insulating layer and a pixel defining layer according to some embodiments.

FIG. 10 shows the sub-pixels SP in the display area DA as a schematic cross-sectional structure taken along the line A-A′ of FIG. 1 and the cathode connection area CCA in the non-display area NDA as a schematic cross-sectional structure taken along line B-B′ of FIG. 1 together. FIG. 10 schematically shows an area corresponding to the cross-sectional structure described above with reference to FIG. 6.

With reference to FIGS. 10 and 11, a disposition relationship between layers in the display area DA and layers in the cathode connection area CCA may be clearly understood. For convenience of description, other layers on the light emitting element layer LEL are omitted in FIG. 10, and layers other than the substrate SUB, the insulating layer INS, and the pixel defining layer PDL are omitted in FIG. 11.

Referring to FIGS. 10 and 11, the display device 100 according to some embodiments is different from the display device 100 according to the embodiments described with respect to FIGS. 6-9, in that the pixel defining layer PDL includes an under-cut portion UC.

Among layers forming the pixel defining layer PDL, an intermediate layer may have a width shorter than that of the uppermost layer and the lowermost layer, and thus the pixel defining layer PDL may form the first step portion ST1, and may further form the under-cut portion UC.

For example, the pixel defining layer PDL may include first to third pixel defining layers PDL1 to PDL3 sequentially stacked. According to some embodiments, the second pixel defining layer PDL2 may have a width shorter than that of the first pixel defining layer PDL1. The second pixel defining layer PDL2 may have a width shorter than that of the third pixel defining layer PDL3. Accordingly, the second pixel defining layer PDL2 may have a structure that is recessed inward with respect to the first and third pixel defining layers PDL1 and PDL3. In this case, the third pixel defining layer PDL3 located on the second pixel defining layer PDL2 may form a tip structure that protrudes with respect to an end of the second pixel defining layer PDL2.

According to some embodiments, as a portion of the pixel defining layer PDL includes the under-cut portion UC to form the tip structure, at least a portion of the emission structure EMS formed to cover the pixel defining layer PDL may be cut accurately, and a risk of a leakage current or the like may be further reduced.

Meanwhile, according to some embodiments, the first slope line SL1 may be formed in the pixel defining layer PDL. The first slope line SL1 may be a virtual line connecting ends of each of the lowermost layer of the pixel defining layer PDL (for example, the first pixel defining layer PDL1) and the uppermost layer of the pixel defining layer PDL (for example, the third pixel defining layer PDL3).

In addition, similarly to the embodiments described above with respect to FIGS. 6-9, the second angle AG2 may be smaller than the first angle AG1, and thus the insulating layer INS patterned in the same process as the pixel defining layer PDL may cause a connection structure of the second connection line CCE2 to be thoroughly maintained.

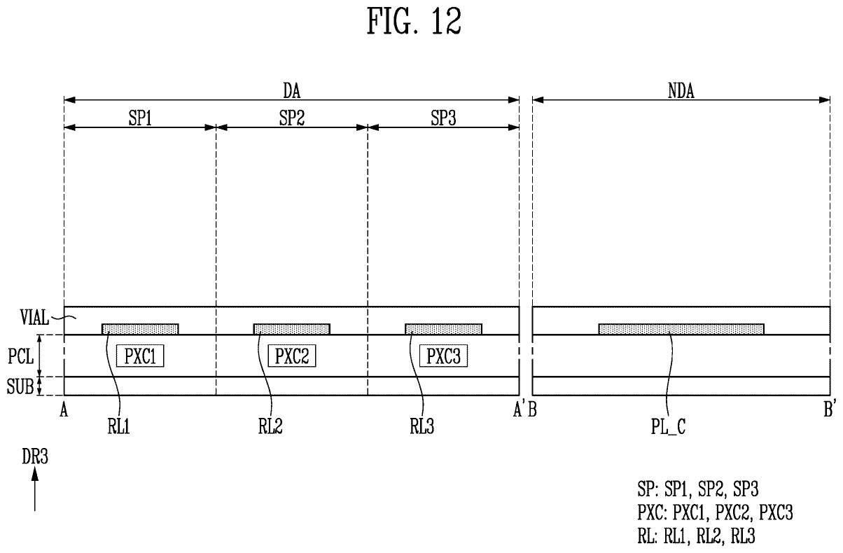

With reference to FIGS. 12 to 23, a method of manufacturing a display device 100 according to some embodiments is described. Some disclosure that may overlap the content described above may be briefly described or may not be repeated.

First, a method of manufacturing the display device 100 according to the embodiments described with respect to FIGS. 6-9 is described with reference to FIGS. 12 to 19.

FIGS. 12 to 19 are schematic cross-sectional views for each process operation illustrating the method of manufacturing the display device according to some embodiments (e.g., the embodiments described with respect to FIGS. 6-9). For convenience of description, FIGS. 12 to 19 are shown based on the cross-sectional structure described above with reference to FIG. 6.

Referring to FIG. 12, the substrate SUB may be provided, the pixel circuits PXC may be patterned on the substrate SUB to form the pixel circuit layer PCL, the reflective layers RL and the cathode power line PL_C may be patterned on the pixel circuit layer PCL, and the interlayer insulating layer VIAL may be formed.

According to some embodiments, conductive layer or insulating layer on the substrate SUB may be formed based on a typical process for manufacturing a semiconductor device. For example, the conductive layer or the insulating layer on a base layer BSL may be formed by a photolithography process, etched by various methods (wet etching, dry etching, and the like), and deposited by various methods (sputtering, a chemical vapor deposition method, and the like). In addition, a photoresist material used to form an etch mask may be a negative type or may be a positive type. Embodiments according to the present disclosure are not necessarily limited to a specific example.

In this operation, the respective first to third reflective layers RL1 to RL3 may be patterned in an area where the first to third sub-pixels SP1 to SP3 are to be formed in the display area DA. The cathode power line PL_C may be patterned in the non-display area NDA.

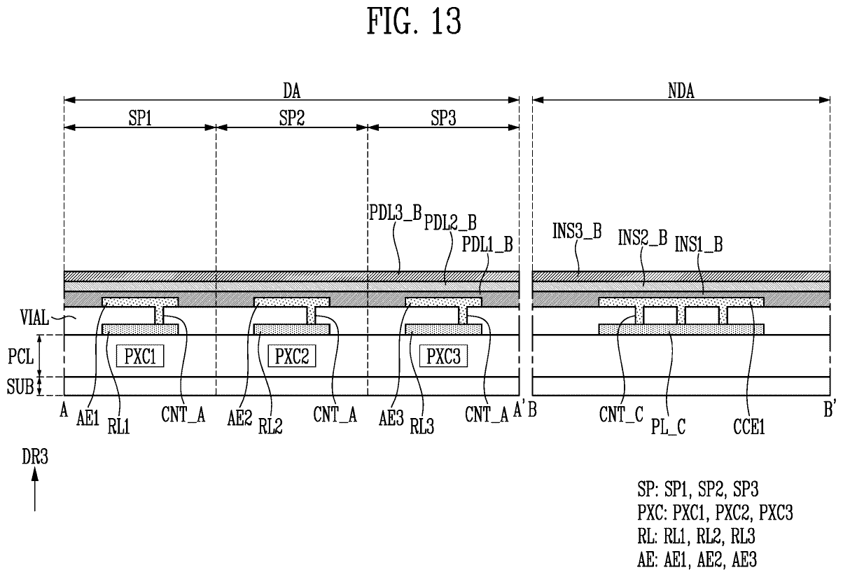

Referring to FIG. 13, the anode electrode AE and first to third base pixel defining layers PDL1_B to PDL3_B may be formed in the display area DA, and the first connection line CCE1 and first to third base insulating layers INS1_B to INS3_B may be formed in the non-display area NDA.

In this operation, the first to third anode electrodes AE1 to AE3 may be patterned and may be electrically connected to the first to third reflective layers RL1 to RL3 through the anode contact portion CNT_A, respectively. The first connection line CCE1 may be electrically connected to the cathode power line PL_C through a plurality of cathode contact portions CNT_C.

According to some embodiments, respective first to third base pixel defining layers PDL1_B to PDL3_B may be layers for manufacturing the first to third pixel defining layers PDL1 to PDL3, and may include a material corresponding to the first to third pixel defining layers PDL1 to PDL3. The respective first to third base insulating layers INS1_B to INS3_B may be layers for manufacturing the first to third insulating layers INS1 to INS3, and may include a material corresponding to the first to third insulating layers INS1 to INS3.

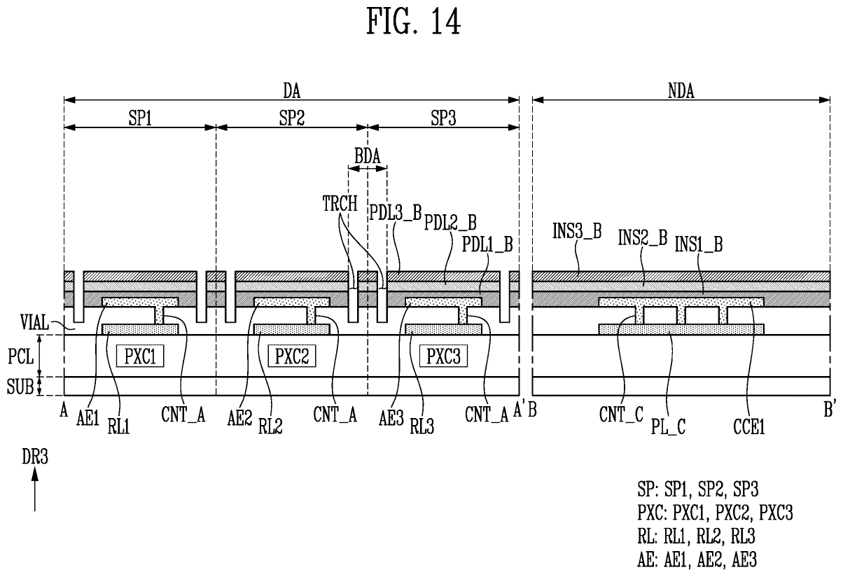

Referring to FIG. 14, at least a portion of the first to third base pixel defining layers PDL1_B to PDL3_B and the interlayer insulating layer VIAL may be etched (for example, dry etched), and the trench TRCH may be formed.

In this operation, the trench TRCH may be formed in a boundary area BDA between adjacent sub-pixels SP.

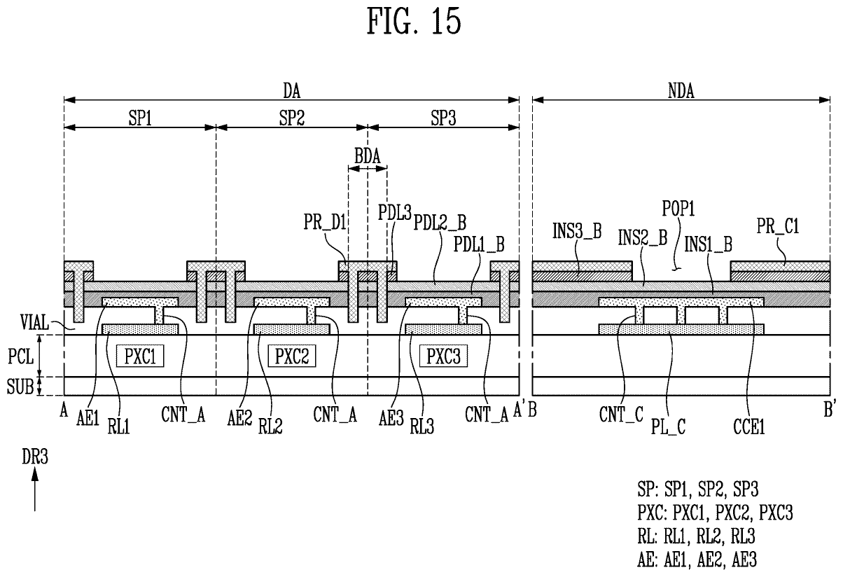

Referring to FIG. 15, at least a portion of the third base pixel defining layer PDL3_B may be etched to provide the third pixel defining layer PDL3 and expose the second base pixel defining layer PDL2_B, and at least a portion of the third base insulating layer INS3_B may be removed to expose at least a portion of the second base insulating layer INS2_B.

In this operation, at least a portion may pattern a first pixel defining photoresist layer PR_D1 located in an area where the third pixel defining layer PDL3 is to be provided, and the third base pixel defining layer PDL3_B may be etched using the first pixel defining photoresist layer PR_D1 as an etch mask. According to some embodiments, the first pixel defining photoresist layer PR_D1 may overlap the third pixel defining layer PDL3 in the plane view.

In this operation, a first outer photoresist layer PR_C1 may be patterned on the third base insulating layer INS3_B, at least a portion of the third base insulating layer INS3_B may be removed using the first outer photoresist layer PR_C1 as an etch mask, and the second base insulating layer INS2_B may be exposed in an area where the first outer photoresist layer PR_C1 is not located.

According to some embodiments, the first outer photoresist layer PR_C1 may include a first photoresist opening POP1. In this operation, an etching process on an area corresponding to the first photoresist opening POP1 may be performed.

According to some embodiments, the first pixel defining photoresist layer PR_D1 and the first outer photoresist layer PR_C1 may be patterned in the same process.

After this operation is performed, the first pixel defining photoresist layer PR_D1 and the first outer photoresist layer PR_C1 may be removed based on a process of ashing or the like.

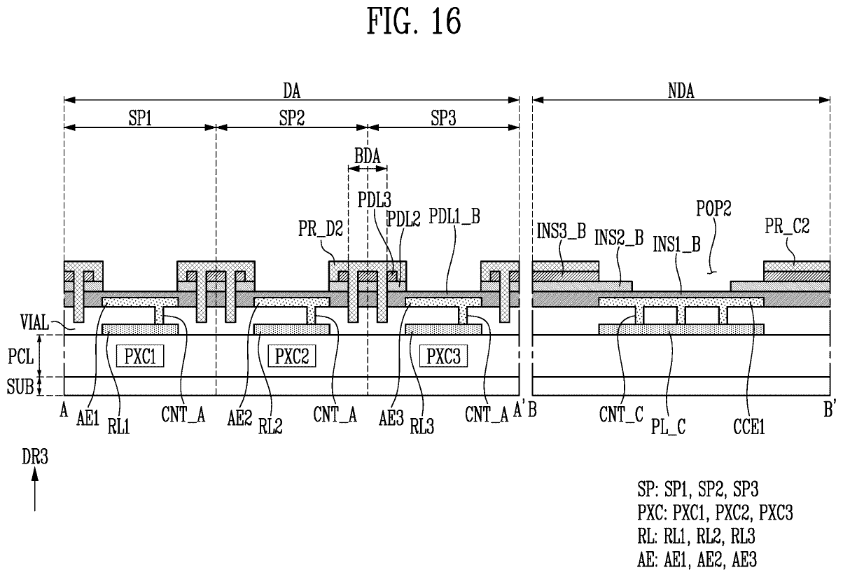

Referring to FIG. 16, at least a portion of the second base pixel defining layer PDL2_B may be etched to provide the second pixel defining layer PDL2 and expose the first base pixel defining layer PDL1_B, at least a portion of the third base insulating layer INS3_B may be removed to expose a portion of an upper surface of the second base insulating layer INS2_B, and at least a portion of the second base insulating layer INS2_B may be removed to expose at least a portion of the first base insulating layer INS1_B.

In this operation, at least a portion may pattern a second pixel defining photoresist layer PR_D2 located in an area where the second pixel defining layer PDL2 is to be provided, and the second base pixel defining layer PDL2_B may be etched using the second pixel defining photoresist layer PR_D2 as an etch mask. According to some embodiments, the second pixel defining photoresist layer PR_D2 may overlap the second pixel defining layer PDL2 in the plan view. In this operation, the third pixel defining layer PDL3 may not be etched. In addition, the second pixel defining photoresist layer PR_D2 may have a width larger than that of the first pixel defining photoresist layer PR_D1, and thus the second pixel defining layer PDL2 may be manufactured to have a width larger than that of the third pixel defining layer PDL3.

In this operation, a second outer photoresist layer PR_C2 may be patterned on the third base insulating layer INS3_B, and at least a portion of each of the third base insulating layer INS3_B and the second base insulating layer INS2_B may be removed using the second outer photoresist layer PR_C2 as an etch mask. Accordingly, an upper surface of the second base insulating layer INS2_B may be exposed in an area where the second outer photoresist layer PR_C2 is not located, and the first base insulating layer INS1_B may be exposed.

According to some embodiments, the second outer photoresist layer PR_C2 may include a second photoresist opening POP2. In this operation, an etching process on an area corresponding to the second photoresist opening POP2 may be performed. According to some embodiments, the second photoresist opening POP2 may be larger than the first photoresist opening POP1 described in the previous operation. Accordingly, at least a portion of the third base insulating layer INS3_B covered by the first outer photoresist layer PR_C1 in the previous operation may be etched in this operation.

According to some embodiments, the second pixel defining photoresist layer PR_D2 and the second outer photoresist layer PR_C2 may be patterned in the same process.

After this operation is performed, the second pixel defining photoresist layer PR_D2 and the second outer photoresist layer PR_C2 may be removed based on a process of ashing or the like.

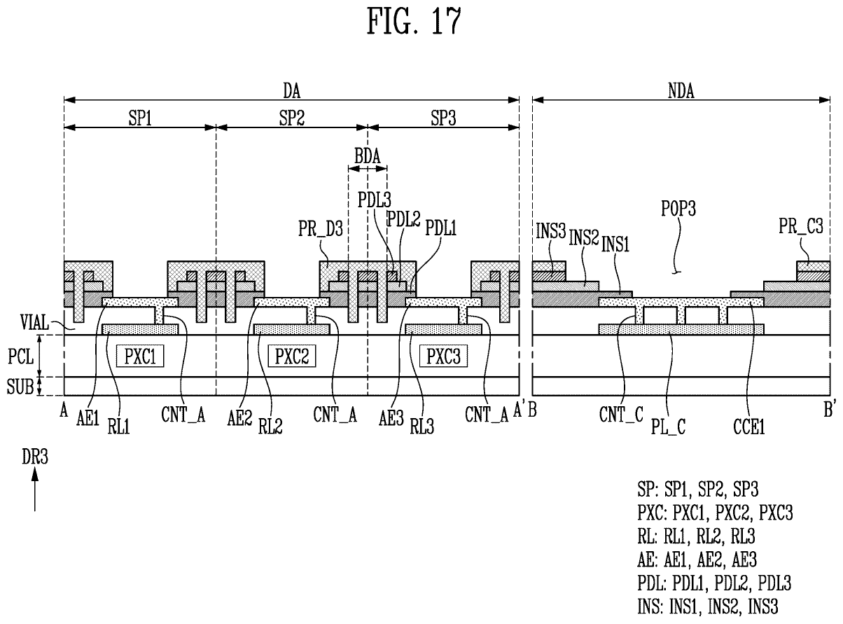

Referring to FIG. 17, at least a portion of the first base pixel defining layer PDL1_B may be etched to provide the first pixel defining layer PDL1 and expose the anode electrode AE, at least a portion of the third base insulating layer INS3_B may be removed to expose a portion of an upper surface of the second base insulating layer INS2_B, at least a portion of the second base insulating layer INS2_B may be removed to expose at least a portion of an upper surface of the first base insulating layer INS1_B, and at least a portion of the first base insulating layer INS1_B may be removed to expose at least a portion of the first connection line CCE1.

In this operation, at least a portion may pattern a third pixel defining photoresist layer PR_D3 located in an area where the first pixel defining layer PDL1 is to be provided, and first base pixel defining layer PDL1_B may be etched using the third pixel defining photoresist layer PR_D3 as an etch mask. According to some embodiments, the third pixel defining photoresist layer PR_D3 may overlap the first pixel defining layer PDL1 in the plane view. In this operation, the second and third pixel defining layers PDL2 and PDL3 may not be etched. In addition, the third pixel defining photoresist layer PR_D3 may have a width larger than that of the first and second pixel defining photoresist layers PR_D1 and PR_D2, and thus the first pixel defining layer PDL1 may be manufactured to have a width larger than that of the second and third pixel defining layers PDL2 and PDL3.

In this operation, a third outer photoresist layer PR_C3 may be patterned on the third base insulating layer INS3_B, and at least a portion of each of the third base insulating layer INS3_B, the second base insulating layer INS2_B, and the first base insulating layer INS1_B using the third outer photoresist layer PR_C3 as an etch mask. Accordingly, an upper surface of the first and second base insulating layers INS1_B and INS2_B may be exposed in an area where the third outer photoresist layer PR_C3 is not located, and the anode electrode AE may be exposed. Accordingly, the first to third insulating layers INS1 to INS3 may be provided.

According to some embodiments, the third outer photoresist layer PR_C3 may include a third photoresist opening POP3. In this operation, an etching process on an area corresponding to the third photoresist opening POP3 may be performed. According to some embodiments, the third photoresist opening POP3 may be larger than the second photoresist opening POP2 described in the previous operation. Accordingly, at least a portion of the second and third base insulating layers INS2_B and INS3_B covered by the second outer photoresist layer PR_C2 in the previous operation may be etched in this operation. Accordingly, the insulating layer INS forming a relatively gentle slope may be provided.

According to some embodiments, the third pixel defining photoresist layer PR_D3 and the third outer photoresist layer PR_C3 may be patterned in the same process.

After this operation is performed, the third pixel defining photoresist layer PR_D3 and the third outer photoresist layer PR_C3 may be removed based on a process of ashing or the like.

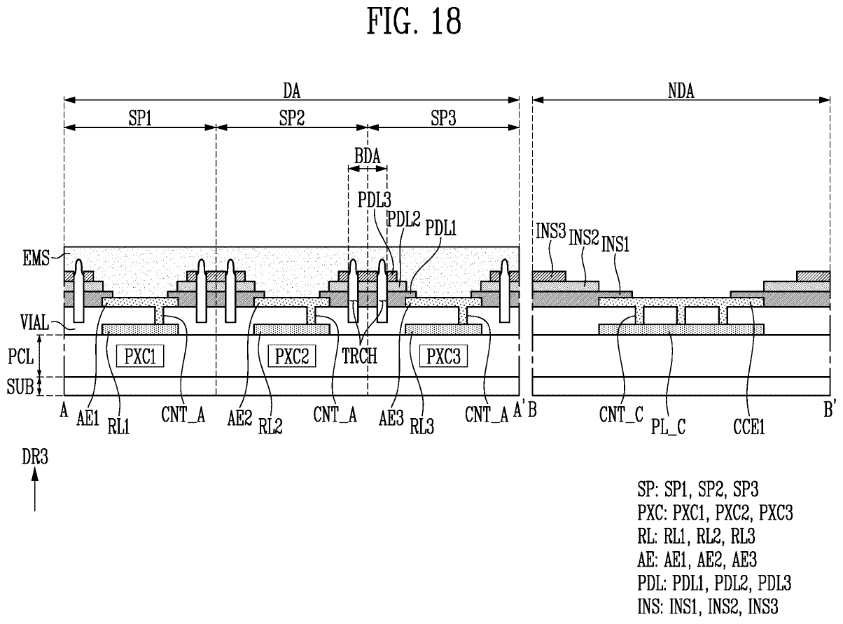

Referring to FIG. 18, the emission structure EMS may be formed across the sub-pixels SP in the display area DA.

In this operation, the emission structure EMS may be formed through a method of vacuum deposition, inkjet printing, and the like, but embodiments according to the present disclosure are not limited thereto.

In this operation, at least a portion of the emission structure EMS may be cut by the trench TRCH.

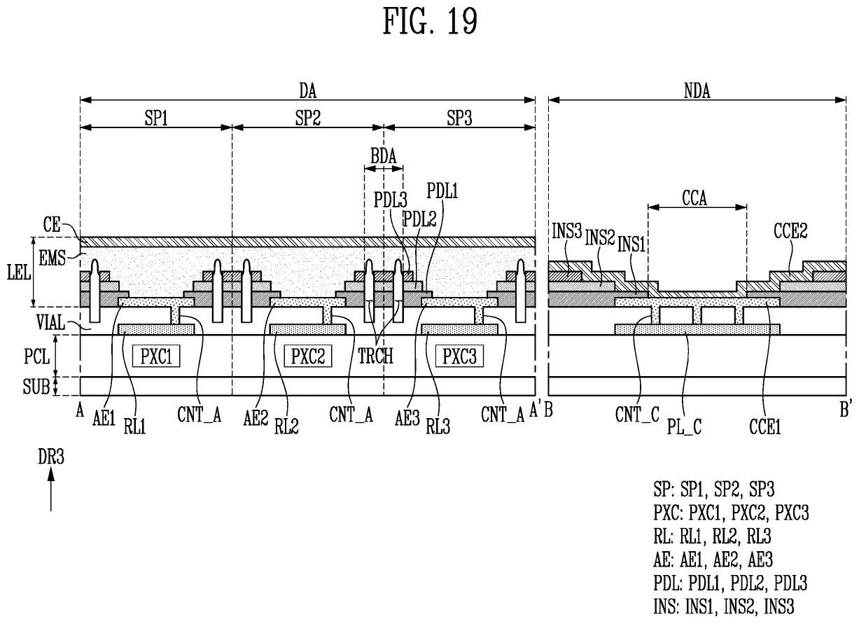

Referring to FIG. 19, a conductive layer may be formed across the display area DA and the non-display area NDA.

In this operation, the cathode electrode CE may be formed in the display area DA, and the second connection line CCE2 may be formed in the non-display area NDA.

In this operation, the second connection line CCE2 and the first connection line CCE1 may contact each other, and the cathode connection area CCA may be defined.

In this operation, even though the second connection line CCE2 covers the insulating layer INS having a step cross-section, because the insulating layer INS forms a relatively gentle slope, a structure of the second connection line CCE2 may be maintained continuously.

Thereafter, according to some embodiments, other layers of the encapsulation layer TFE and the like may be further located on the cathode electrode CE, and the display device 100 according to some embodiments may be provided.

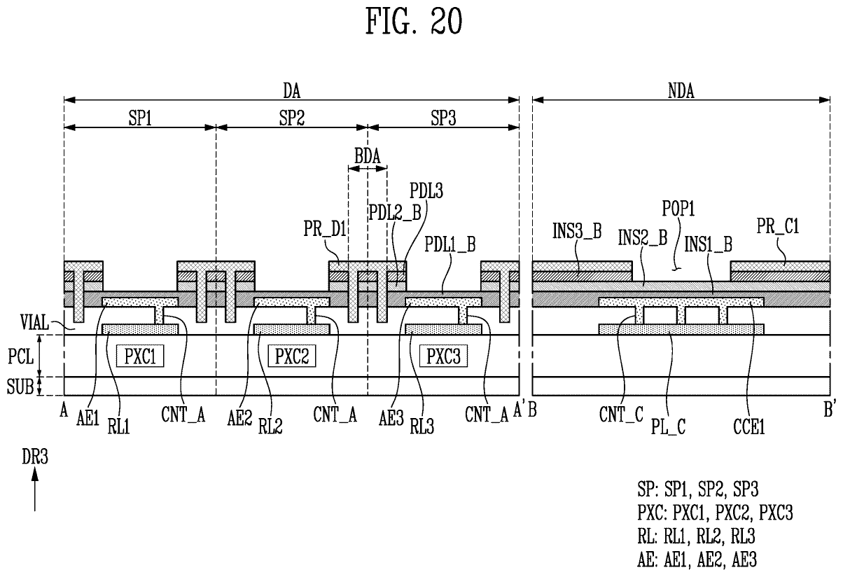

Next, with reference to FIGS. 20 to 23, a method of manufacturing the display device 100 according to the embodiments described with respect to FIGS. 10 and 11 is described. Some disclosure that may overlap the content described above may be briefly described or may not be repeated.

FIGS. 20 to 23 are schematic cross-sectional views for each process operation illustrating the method of manufacturing the display device according to some embodiments. For convenience of description, FIGS. 20 to 23 are shown based on the cross-sectional structure described above with reference to FIG. 10.

In the method of manufacturing the display device 100 according to some embodiments, the process operations described above with reference to FIGS. 12 to 14 may be identically performed.

Referring to FIG. 20, at least a portion of the third base pixel defining layer PDL3_B may be etched to provide the third pixel defining layer PDL3, at least a portion of the second base pixel defining layer PDL2_B may be etched to expose the first base pixel defining layer PDL1_B, and at least a portion of the third base insulating layer INS3_B may be removed to expose at least a portion of the second base insulating layer INS2_B.

In this operation, the third pixel defining layer PDL3 may be patterned to have a relatively great width. Accordingly, the first pixel defining photoresist layer PR_D1 may be patterned to have a relatively great width compared to the embodiments described above. In addition, the second and third base pixel defining layers PDL2_B and PDL3_B may be collectively etched based on the first pixel definition photoresist layer PR_D1.

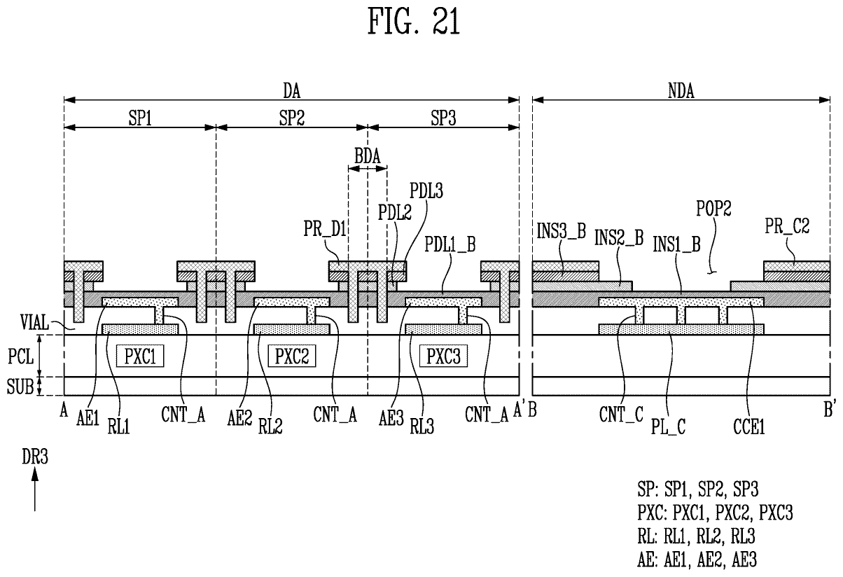

Referring to FIG. 21, at least a portion of the second base pixel defining layer PDL2_B may be further etched to provide the second pixel defining layer PDL2, the undercut portion UC may be formed, at least a portion of the third base insulating layer INS3_B may be removed to expose a portion of an upper surface of the second base insulating layer INS2_B, and at least a portion of the second base insulating layer INS2_B may be removed to expose at least a portion of the first base insulating layer INS1_B.

In this operation, the second base pixel defining layer PDL2_B may be further etched based on the first pixel defining photoresist layer PR_D1, and thus the second pixel defining layer PDL2 more recessed inward compared to the third pixel defining layer PDL3 may be provided. At this time, because the third pixel defining layer PDL3 and the second pixel defining layer PDL2 may include different materials, the under-cut portion UC may be formed appropriately.

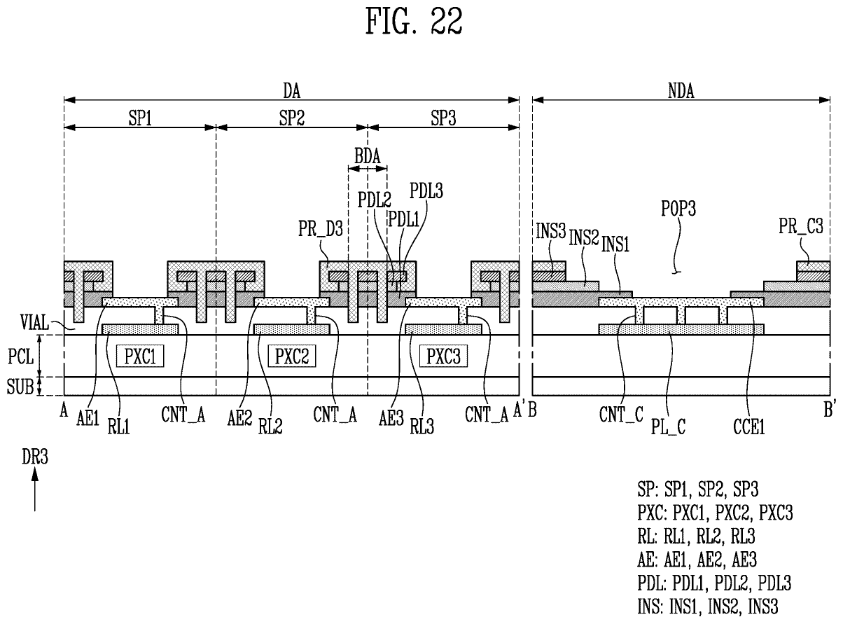

Referring to FIG. 22, at least a portion of the first base pixel defining layer PDL1_B may be etched to provide the first pixel defining layer PDL1 and expose the anode electrode AE. In addition, at least a portion of the third base insulating layer INS3_B may be removed to expose a portion of an upper surface of the second base insulating layer INS2_B, at least a portion of the second base insulating layer INS2_B may be removed to expose a portion of an upper surface of the first base insulating layer INS1_B, at least a portion of the first base insulating layer INS1_B may be removed to expose at least a portion of the first connection line CCE1, and thus the first to third insulating layers INS1 to INS3 may be provided.

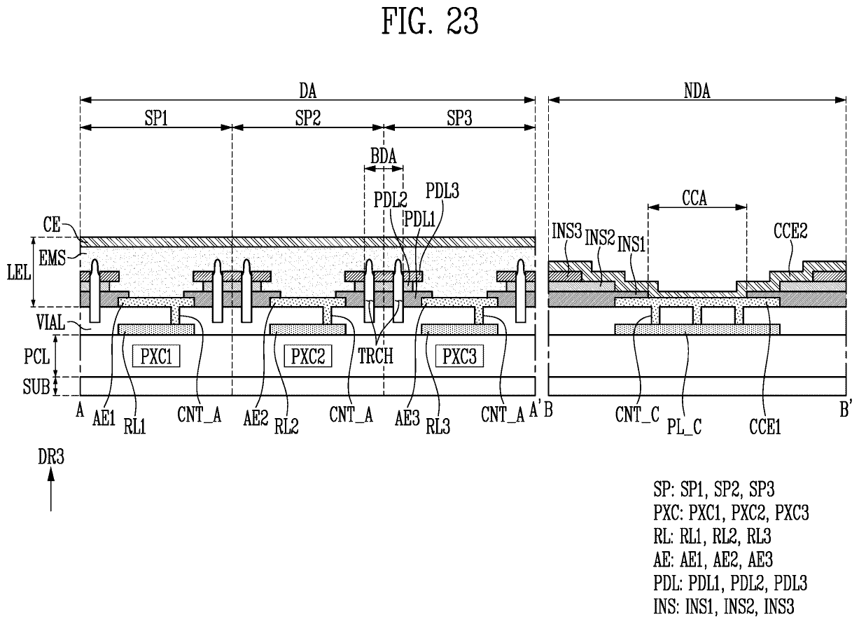

Referring to FIG. 23, the emission structure EMS may be arranged across the sub-pixels SP, the cathode electrode CE may be located on the emission structure EMS, and the second connection line CCE2 covering the insulating layer INS and the first connection line CCE1 may be located.

Thereafter, according to some embodiments, other layers of the encapsulation layer TFE and the like may be further located on the cathode electrode CE, and the display device 100 according to some embodiments may be provided.

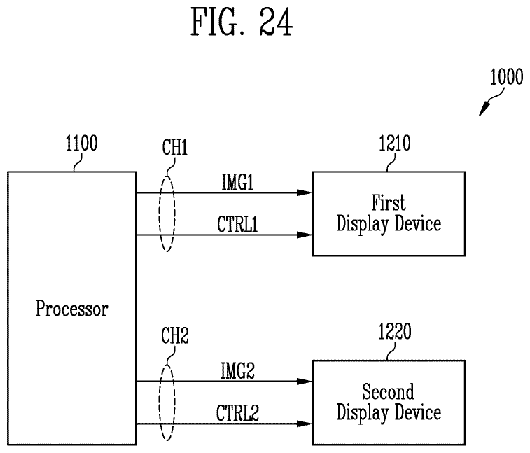

FIG. 24 is a block diagram illustrating aspects of an electronic device according to some embodiments of the present disclosure.

Referring to FIG. 24, the electronic device 1000 may include a processor 1100 and one or more display devices 1210 and 1220. The electronic device 1000 may implement a display system.

The processor 1100 may perform various tasks and calculations. According to some embodiments, the processor 1100 may include an application processor, a graphic processor, a microprocessor, a central processing unit (CPU), and the like.

The processor 1100 may be connected to other components of the electronic device 1000 through a bus system and may control the other components.

According to an embodiment, the processor 1100 may provide input image data to the display device 1210, 1220, and the display device 1210, 1220 may display images based on the input image data provided by the processor 1100.

In FIG. 24, the electronic device 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1.

The electronic device 1000 may include a computing system providing an image display function, such as a portable computer, a mobile phone, a smart phone, a tablet personal computer (PC), a smart watch, a watch phone, a portable multimedia player (PMP), a navigation device, and an ultra mobile personal computer (UMPC). In addition, the electronic device 1000 may include at least one of a head mounted display (HMD) device, a virtual reality (VR) device, a mixed reality (MR) device, or an augmented reality (AR) device.

According to an embodiment, the electronic device 1000 may further include a memory device, a storage device, an input/output(1/O) device, a power supply.

The memory device may store data needed to perform the operation of the electronic device. For example, the memory device may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

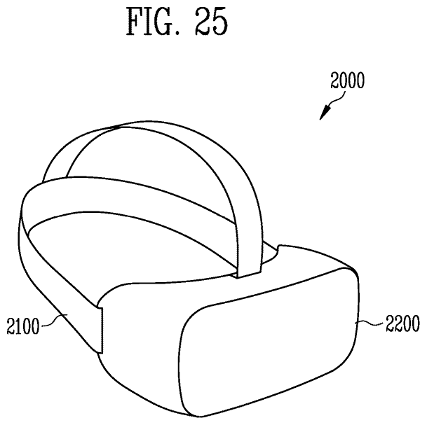

FIG. 25 is a perspective view illustrating an application example of the electronic device of FIG. 24.

Referring to FIG. 25, the electronic device 1000 of FIG. 24 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device receiving case 2200 may receive the first and second display devices 1210 and 1220 of FIG. 24. The display device receiving case 2200 may further receive the processor 1100 of FIG. 24.

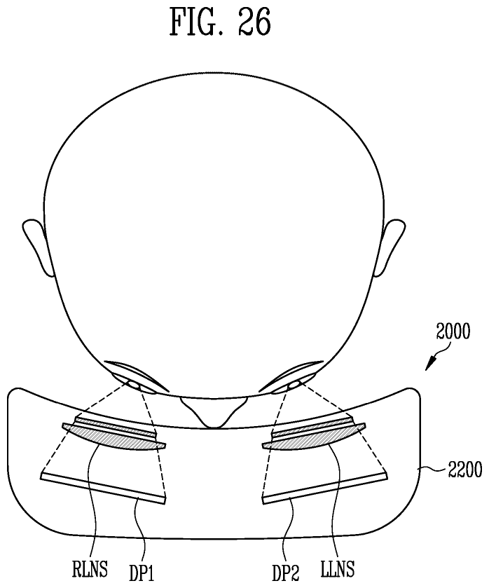

FIG. 26 is a diagram illustrating the head mounted display device of FIG. 25 worn by a user.

Referring to FIG. 26, a first display panel DP1 of the first display device 1210 and a second display panel DP2 of the second display device 1220 are located in the head mounted display device 2000. The head mounted display device 2000 may further include one or more lenses LLNS and RLNS.

Within the display device receiving case 2200, the right eye lens RLNS may be located between the first display device 1210 and a user's right eye. Within the display device receiving case 2200, the left eye lens LLNS may be located between the second display device 1220 and a user's left eye.

An image output from the first display device 1210 may be displayed to the user's right eye through the right eye lens RLNS. The right eye lens RLNS may refract light from the first display device 1210 to be directed toward the user's right eye. The right eye lens RLNS may perform an optical function for adjusting a viewing distance between the first display device 1210 and the user's right eye.

An image output from the second display device 1220 may be displayed to the user's left eye through the left eye lens LLNS. The left eye lens LLNS may refract light from the second display device 1220 to be directed toward the user's left eye. The left eye lens LLNS may perform an optical function for adjusting a viewing distance between the second display device 1220 and the user's left eye.

According to some embodiments, each of the right eye lens RLNS and the left eye lens LLNS may include an optical lens having a pancake-shaped cross-section. According to some embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

As described above, although aspects of some embodiments of the present disclosure have been described with reference to the disclosed embodiments, those skilled in the art or those having a common knowledge in the art will understand that the disclosure may be variously modified and changed without departing from the spirit and scope of embodiments according to the present disclosure as described in the appended claims and their equivalents.

Therefore, the characteristics of embodiments according to the present disclosure are not limited to the characteristics specifically described in the detailed description of the specification, but should be defined by the appended claims, and their equivalents.

What is claimed is:

1. A display device including a display area where sub-pixels are located and a non-display area, the display device comprising:
a pixel circuit layer including a pixel circuit on a substrate;
an interlayer insulating layer on the pixel circuit layer; and
a light emitting element layer on the interlayer insulating layer,
wherein the light emitting element layer comprises:
a light emitting element including an anode electrode, a cathode electrode, and a emission structure electrically connected between the anode electrode and the cathode electrode in the display area;
an insulating layer disposed on the interlayer insulating layer in the non-display area,
a pixel defining layer on the interlayer insulating layer and adjacent to the anode electrode; and
a trench passing through at least a portion of the pixel defining layer and formed in a boundary area between the sub-pixels,
the pixel defining layer forms a first slope line having a first angle with a plane where the substrate is located, the insulating layer forms a second slope line having a second angle with the plane, and
the second angle is smaller than the first angle.

2. The display device according to claim 1, wherein the pixel defining layer includes a plurality of layers having different widths and forming a first step portion,
the insulating layer includes a plurality of layers having different widths and forming a second step portion, and
the first step portion and the second step portion form different structures.

3. The display device according to claim 1, wherein the pixel defining layer and the insulating layer include one or more of silicon oxide (SiₓO_{y}) and silicon nitride (SiₓN_{y}).

4. The display device according to claim 1, wherein the pixel defining layer includes a first pixel defining layer, a second pixel defining layer on the first pixel defining layer, and a third pixel defining layer on the second pixel defining layer,
the insulating layer includes a first insulating layer, a second insulating layer on the first insulating layer, and a third insulating layer on the second insulating layer,
the first pixel defining layer and the first insulating layer are in a same layer,
the second pixel defining layer and the second insulating layer are in a same layer, and
the third pixel defining layer and the third insulating layer are in a same layer.

5. The display device according to claim 4, wherein the first slope line is a virtual line connecting ends of each of the first pixel defining layer and the third pixel defining layer, and
the second slope line is a virtual line connecting ends of each of the first insulating layer and the third insulating layer.

6. The display device according to claim 4, wherein the second pixel defining layer includes a material different from that of the first pixel defining layer and the third pixel defining layer, and
the second insulating layer includes a material different from that of the first insulating layer and the third insulating layer.

7. The display device according to claim 4, wherein the second pixel defining layer has a width larger than that of the third pixel defining layer,
the first pixel defining layer has a width larger than that of the second pixel defining layer,
the second insulating layer has a width larger than that of the third insulating layer, and
the first insulating layer has a width larger than that of the second insulating layer.

8. The display device according to claim 4, wherein the second pixel defining layer has a width smaller than that of the third pixel defining layer,
the first pixel defining layer has a width larger than that of the second pixel defining layer,
the second insulating layer has a width larger than that of the third insulating layer, and
the first insulating layer has a width larger than that of the second insulating layer.

9. The display device according to claim 8, wherein the pixel defining layer includes an under-cut portion at least partially recessed.

10. The display device according to claim 1, wherein the light emitting element layer comprises in the non-display area:
a first connection line in a same layer as the anode electrode;
an insulating layer covering a portion of the first connection line; and
a second connection line in a same layer as the cathode electrode and electrically connected to the first connection line.

11. The display device according to claim 10, further comprising:
a reflective layer on the pixel circuit layer in the display area, covered by the interlayer insulating layer, and electrically connecting the anode electrode and the pixel circuit; and
a cathode power line on the pixel circuit layer in the non-display area, covered by the interlayer insulating layer, electrically connected to the first connection line, and in a same layer as the reflective layer,
wherein the trench partially passes through at least a portion of the interlayer insulating layer,
the substrate is a silicon substrate,
the emission structure is arranged across the sub-pixels, and at least a portion of the emission structure is disconnected by the trench.

12. A display device including a display area including sub-pixel areas, the display device comprising:
a pixel circuit layer including a pixel circuit on a substrate;
an interlayer insulating layer on the pixel circuit layer; and
a light emitting element layer on the interlayer insulating layer,
wherein the light emitting element layer comprises in the display area:
an anode electrode, a cathode electrode, and a light emitting element electrically connected between the anode electrode and the cathode electrode;
a pixel defining layer on the interlayer insulating layer and covering a portion of the anode electrode; and
a trench passing through the pixel defining layer and formed in a boundary area between the sub-pixel areas,
the pixel defining layer includes a first pixel defining layer, a second pixel defining layer on the first pixel defining layer, and a third pixel defining layer on the second pixel defining layer, and
the second pixel defining layer has a width smaller than that of the first pixel defining layer and the third pixel defining layer.

13. A method of manufacturing a display device, the method comprising:
patterning a first connection line on a substrate;
forming a base insulating layer covering the first connection line, and including a first base insulating layer, a second base insulating layer on the first base insulating layer, and a third base insulating layer on the second base insulating layer;
exposing the second base insulating layer by etching a portion of the third base insulating layer;
exposing the first base insulating layer by etching another portion of the third base insulating layer and a portion of the second base insulating layer;
exposing the first connection line by etching still another portion of the third base insulating layer, another portion of the second base insulating layer, and a portion of the first base insulating layer; and
patterning a second connection line electrically connected to the first connection line.

14. The method according to claim 13, wherein exposing the second base insulating layer comprises:
patterning a first outer photoresist layer including a first photoresist opening; and
etching the third base insulating layer using the first outer photoresist layer as an etch mask, exposing the first base insulating layer comprises:
patterning a second outer photoresist layer including a second photoresist opening; and
etching the second base insulating layer using the second outer photoresist layer as an etch mask,
exposing the first connection line comprises:
patterning a third outer photoresist layer including a third photoresist opening; and
etching the first base insulating layer using the third outer photoresist layer as an etch mask, and
the second photoresist opening is larger than the first photoresist opening, and the third photoresist opening is larger than the second photoresist opening.

15. The method according to claim 14, further comprising:
patterning an anode electrode on the substrate; and
forming a base pixel defining layer covering the anode electrode,
wherein the base pixel defining layer includes a first base pixel defining layer, a second base pixel defining layer, and a third base pixel defining layer,
the anode electrode and the first connection line are formed in a same process,
the first base pixel defining layer and the first base insulating layer are formed in a same process,
the second base pixel defining layer and the second base insulating layer are formed in a same process, and
the third base pixel defining layer and the third base insulating layer are formed in a same process.

16. The method according to claim 15, further comprising:
providing a third pixel defining layer by patterning a first pixel defining photoresist layer and etching a portion of the third base insulating layer using the first pixel defining photoresist layer as an etch mask;
providing a second pixel defining layer by patterning a second pixel defining photoresist layer and etching a portion of the second base insulating layer using the second pixel defining photoresist layer as an etch mask; and
providing a first pixel defining layer by patterning a third pixel defining photoresist layer and etching a portion of the first base insulating layer using the third pixel defining photoresist layer as an etch mask,
wherein the first pixel defining photoresist layer and the first outer photoresist layer are formed in a same process,
the second pixel defining photoresist layer and the second outer photoresist layer are formed in a same process,
the third pixel defining photoresist layer and the third outer photoresist layer are formed in a same process, and
exposing the first connection line comprises:
providing a third insulating layer by etching the third base insulating layer;
providing a second insulating layer by etching the second base insulating layer; and
providing a first insulating layer by etching the first base insulating layer.

17. The method according to claim 16, wherein the second pixel defining photoresist layer has a width larger than that of the first pixel defining photoresist layer, and
the third pixel defining photoresist layer has a width larger than that of the second pixel defining photoresist layer.

18. The method according to claim 16, further comprising:
forming a trench passing through the first pixel defining layer, the second pixel defining layer, and the third pixel defining layer; and
forming a emission structure electrically connected to the anode electrode and covering the first pixel defining layer, the second pixel defining layer, and the third pixel defining layer,
wherein the base insulating layer forms a slope less than that of the pixel defining layer.

19. The method according to claim 16, wherein the second pixel defining layer has a width larger than that of the third pixel defining layer,
the first pixel defining layer has a width larger than that of the second pixel defining layer,
the second insulating layer has a width larger than that of the third insulating layer, and
the first insulating layer has a width larger than that of the second insulating layer.

20. The method according to claim 16, wherein the second pixel defining layer has a width smaller than that of the third pixel defining layer,
the first pixel defining layer has a width larger than that of the second pixel defining layer,
the second insulating layer has a width larger than that of the third insulating layer, and
the first insulating layer has a width larger than that of the second insulating layer.

21. An electronic device, comprising:
a processor configured to provide input image data;
a display device configured to display an image based on the input image data, the display device including sub-pixel areas; and
a power supply configured to supply power to the display device,
wherein the display device comprises:
a display area where sub-pixels are located and a non-display area;
a pixel circuit layer including a pixel circuit on a substrate;
an interlayer insulating layer on the pixel circuit layer; and
a light emitting element layer on the interlayer insulating layer,
wherein the light emitting element layer comprises:
a light emitting element including an anode electrode, a cathode electrode, and a emission structure electrically connected between the anode electrode and the cathode electrode in the display area;
an insulating layer disposed on the interlayer insulating layer in the non-display area,
a pixel defining layer on the interlayer insulating layer and adjacent to the anode electrode; and
a trench passing through at least a portion of the pixel defining layer and formed in a boundary area between the sub-pixels,
wherein the pixel defining layer forms a first slope line having a first angle with a plane where the substrate is located, the insulating layer forms a second slope line having a second angle with the plane, and
the second angle is smaller than the first angle.
